(19) United States
(12) Patent Application Publication
(10) Pub. No.: US 2009/0087958 A1
(43) Pub. Date: Apr. 2, 2009

(54) SEMICONDUCTOR DEVICE AND MANUFACTURING METHOD THEREOF

(75) Inventor: Hiroyuki UCHIYAMA, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC., Tokyo (JP)

(21) Appl. No.: 12/260,626

(22) Filed: Oct. 29, 2008

Related U.S. Application Data
(62) Division of application No. 11/344,097, filed on Feb. 1, 2006.

(30) Foreign Application Priority Data
Feb. 2, 2005 (JP) 2005-026100

(51) Int. Cl. H01L 21/02

(52) U.S. Cl. 438/387; 257/E21.008

(57) ABSTRACT

A semiconductor device and a manufacturing method thereof which enable to secure high yield and increase the capacity of a capacitor are provided. The semiconductor device according to the present invention includes: a plurality of capacitor layers laminated, each capacitor layer including a plurality of storage electrodes, a capacity insulating film covering the surface of the storage electrodes, and a plate electrode provided between the storage electrodes, wherein the plate electrode of each of the laminated capacitor layers are electrically connected to each other and the corresponding storage electrode of each of the laminated capacitor layers are electrically connected to each other.

### TECHNICAL FIELD

The present invention relates to a semiconductor device and a manufacturing method thereof. Particularly, the invention relates to a semiconductor device having a stacked capacitor, and a method of manufacturing the semiconductor device.

### BACKGROUND OF THE INVENTION

Conventionally, in a dynamic random access memory (DRAM) having a stacked capacitor, in order to compensate for a reduction of an electrostatic capacity of the capacitor due to the miniaturization of the DRAM, either the three dimensional size of the capacitor is increased in a height direction, or a highly dielectric material is used for a capacity insulating film.

However, when the height of the capacitor is increased, the embedding of an insulating film and a plate electrode (opposite electrode) to be formed between adjacent capacitors becomes difficult. Particularly, for a cylinder type capacitor, a capacity insulating film and a plate electrode (opposite electrode) need to be formed at the inside of a storage electrode having a cylinder shape. As a result, covering and embedding characteristics are degraded, a leakage current between adjacent cells increases, and coupling noise increases. When the height of the capacitor increases, the height (depth) of a through-hole for connecting between upper and lower wiring layers in a peripheral circuit area also increases. Consequently, an aspect ratio becomes large, and it becomes difficult to securely embed a conductor into the through-hole.

When the DRAM is further miniaturized, the above two measures need to be employed simultaneously. In other words, it is anticipated that a new material, of which film-forming condition or processing condition is not yet obtained sufficiently as a manufacturing technique, needs to be used to manufacture the capacitor having an increased height, which is already difficult to be manufactured even by using a conventional material. As a result, the developing period may be delayed and the yield may be reduced.

Semiconductor devices having the stacked capacitors are described in, for example, Japanese Patent Application Laid-open Nos. 2001-230388, 2001-111008, 2000-196038, and 2000-156480.

### SUMMARY OF THE INVENTION

The present invention has been achieved to solve the above problems. It is an object of the present invention to provide a semiconductor device that can secure high yield and can increase the capacity of a capacitor, and a method of manufacturing this semiconductor device.

It is another object of the present invention to provide a method of manufacturing a semiconductor device in which a memory cell area and a peripheral circuit area can be manufactured consistently.

The semiconductor device according to the present invention includes: a plurality of capacitor layers laminated, each capacitor layer including a plurality of storage electrodes, a capacity insulating film covering the storage electrodes, and a plate electrode provided between the storage electrodes, wherein the plate electrode of each of the laminated capacitor layers are electrically connected to each other and the corresponding storage electrode of each of the laminated capacitor layers are electrically connected to each other.

The method of manufacturing a semiconductor device according to the present invention includes: a first step of forming a first capacitor layer having a pillar-shaped first storage electrode, a first capacity insulating film that covers a side surface of the first storage electrode, and a first plate electrode that covers at least a part of the side surface of the first storage electrode via the first capacity insulating film, on a semiconductor substrate; and a second step of forming a second capacitor layer having a pillar-shaped second storage electrode that is connected to the first storage electrode, a second capacity insulating film that covers a side surface of the second storage electrode, and a second plate electrode that covers at least a part of the side surface of the second storage electrode via the second capacity insulating film and that is connected to the first plate electrode, on the first capacitor layer.

According to the present invention, since plural capacitor layers are laminated, in order to obtain the same electrostatic capacity, it is possible to restrict the aspect ratio of each capacitor layer compared to single-layer capacitor. In other words, each capacitor layer has a height at which coverage of the capacity insulating film and the conductive film that constitutes the capacitor does not become a problem. When these capacitor layers are laminated, a minimum storage charge necessary to hold information can be secured while securing high yield.

In the method of manufacturing the semiconductor device according to the present invention, a plate electrode in each capacitor layer and contact plugs or wiring layers in the peripheral circuit area are formed using the same material, simultaneously. With this arrangement, increase in the number of manufacturing steps and increase in manufacturing cost can be minimized.

### BRIEF DESCRIPTION OF THE DRAWINGS

The above and other objects, features and advantages of the present invention will become more apparent by reference to the following detailed description of the invention taken in conjunction with the accompanying drawings, wherein:

FIG. 1 is a partial cross-sectional diagram showing one step (formation of an element isolation area 101 to a contact plug 113) in a method of manufacturing a semiconductor device according to a first embodiment of the present invention;

FIG. 2 is a partial cross-sectional diagram showing one step (formation of a tungsten film 114 and a silicon nitride film 115) in a method of manufacturing a semiconductor device according to the first embodiment of the present invention;

FIG. 3 is a partial cross-sectional diagram showing one step (patterning of the tungsten film 114 and the silicon nitride film 115) in a method of manufacturing a semiconductor device according to the first embodiment of the present invention;

FIG. 4 is a partial cross-sectional diagram showing one step (formation of a tantalum oxide film 120 and a silicon oxide film 121) in a method of manufacturing a semiconductor device according to the first embodiment of the present invention;

FIG. 5 is a partial cross-sectional diagram showing one step (etching back of the tantalum oxide film 120 and the silicon oxide film 121) in a method of manufacturing a semiconductor device according to the first embodiment of the present invention;

FIG. 6 is a partial cross-sectional diagram showing one step (formation of a silicon oxide film 122) in a method of manufacturing a semiconductor device according to the first embodiment of the present invention;

FIG. 7 is a partial cross-sectional diagram showing one step (selectively removing of the silicon oxide films 121 and 122) in a method of manufacturing a semiconductor device according to the first embodiment of the present invention;

FIG. 8 is a partial cross-sectional diagram showing one step (formation of a tungsten film 123) in a method of manufacturing a semiconductor device according to the first embodiment of the present invention;

FIG. 9 is a partial cross-sectional diagram showing one step (CMP of the tungsten film 123 to formation of a silicon nitride film 125) in a method of manufacturing a semiconductor device according to the first embodiment of the present invention;

FIG. 10 is a partial cross-sectional diagram showing one step (selectively removing of the silicon nitride film 125 and a cap insulating layer 116) in a method of manufacturing a semiconductor device according to the first embodiment of the present invention;

FIG. 11 is a partial cross-sectional diagram showing one step (formation of a plate electrode 129 and contact plug 130) in a method of manufacturing a semiconductor device according to the first embodiment of the present invention;

FIG. 12 is a partial cross-sectional diagram showing one step (selectively removing of the silicon nitride film 125) in a method of manufacturing a semiconductor device according to the first embodiment of the present invention;

FIG. 13 is a partial cross-sectional diagram showing one step (formation of a tantalum oxide film 131 and a silicon oxide film 132) in a method of manufacturing a semiconductor device according to the first embodiment of the present invention;

FIG. 14 is a partial cross-sectional diagram showing one step (etching back of the tantalum oxide film 131 and the silicon oxide film 132) in a method of manufacturing a semiconductor device according to the first embodiment of the present invention;

FIG. 15 is a partial cross-sectional diagram showing one step (formation of a silicon oxide film 133) in a method of manufacturing a semiconductor device according to the first embodiment of the present invention;

FIG. 16 is a partial cross-sectional diagram showing one step (selectively removing of the silicon oxide films 133 and 131) in a method of manufacturing a semiconductor device according to the first embodiment of the present invention;

FIG. 17 is a partial cross-sectional diagram showing one step (formation of a tungsten film 134) in a method of manufacturing a semiconductor device according to the first embodiment of the present invention;

FIG. 18 is a partial cross-sectional diagram showing one step (CMP of the tungsten film 134 to formation of a silicon nitride film 136) in a method of manufacturing a semiconductor device according to the first embodiment of the present invention;

FIG. 19 is a partial cross-sectional diagram showing one step (selectively removing of the silicon nitride film 136 and a cap insulating layer 127) in a method of manufacturing a semiconductor device according to the first embodiment of the present invention;

FIG. 20 is a partial cross-sectional diagram showing one step (formation of a wiring layer 139) in a method of manufacturing a semiconductor device according to the first embodiment of the present invention;

FIG. 21 is a partial cross-sectional diagram showing one step (formation of a conductive film 214 and a silicon nitride film 215) in a method of manufacturing a semiconductor device according to a second embodiment of the present invention;

FIG. 22 is a partial cross-sectional diagram showing one step (patterning of the conductive film 214 and the silicon nitride film 215) in a method of manufacturing a semiconductor device according to the second embodiment of the present invention;

FIG. 23 is a partial cross-sectional diagram showing one step (formation of a tantalum oxide film 220 and a silicon oxide film 221) in a method of manufacturing a semiconductor device according to the second embodiment of the present invention;

FIG. 24 is a partial cross-sectional diagram showing one step (etching back of the tantalum oxide film 220 and the silicon oxide film 221) in a method of manufacturing a semiconductor device according to the second embodiment of the present invention;

FIG. 25 is a partial cross-sectional diagram showing one step (formation of a silicon oxide film 222) in a method of manufacturing a semiconductor device according to the second embodiment of the present invention;

FIG. 26 is a partial cross-sectional diagram showing one step (selectively removing of the silicon oxide films 221 and 222) in a method of manufacturing a semiconductor device according to the second embodiment of the present invention;

FIG. 27 is a partial cross-sectional diagram showing one step (formation of a tungsten film 223) in a method of manufacturing a semiconductor device according to the second embodiment of the present invention;

FIG. 28 is a partial cross-sectional diagram showing one step (CMP of the tungsten film 123 to formation of a silicon nitride film 223) in a method of manufacturing a semiconductor device according to the second embodiment of the present invention;

FIG. 29 is a partial cross-sectional diagram showing one step (formation of a silicon oxide film 225 to formation of contact plugs 226 and 227) in a method of manufacturing a semiconductor device according to the second embodiment of the present invention;

FIG. 30 is a partial cross-sectional diagram showing one step (formation of a conductive film 228 and a silicon nitride film 229) in a method of manufacturing a semiconductor device according to the second embodiment of the present invention;

FIG. 31 is a partial cross-sectional diagram showing one step (patterning of the conductive film 228, the silicon nitride film 229 and the silicon oxide film 225) in a method of manufacturing a semiconductor device according to the second embodiment of the present invention;

FIG. 32 is a partial cross-sectional diagram showing one step (formation of a tantalum oxide film 234 and a silicon oxide film 235) in a method of manufacturing a semiconductor device according to the second embodiment of the present invention;

FIG. 33 is a partial cross-sectional diagram showing one step (etching back of the tantalum oxide film 234 and the silicon oxide film 235) in a method of manufacturing a semiconductor device according to the second embodiment of the present invention;

FIG. 34 is a partial cross-sectional diagram showing one step (formation of a silicon oxide film 236 to selectively removing the silicon oxide films 236 and 235) in a method of manufacturing a semiconductor device according to the second embodiment of the present invention;

FIG. 35 is a partial cross-sectional diagram showing one step (formation of a storage electrode 237) in a method of manufacturing a semiconductor device according to the second embodiment of the present invention;

FIG. 36 is a partial cross-sectional diagram showing one step (formation of a wiring layer 241) in a method of manufacturing a semiconductor device according to the second embodiment of the present invention; and

FIG. 37 is a cross-sectional diagram of the DRAM when there are four capacitor layers in the second embodiment.

### DETAILED DESCRIPTION OF THE EMBODIMENTS

Exemplary embodiments of the present invention will be explained below with reference to the accompanying drawings.

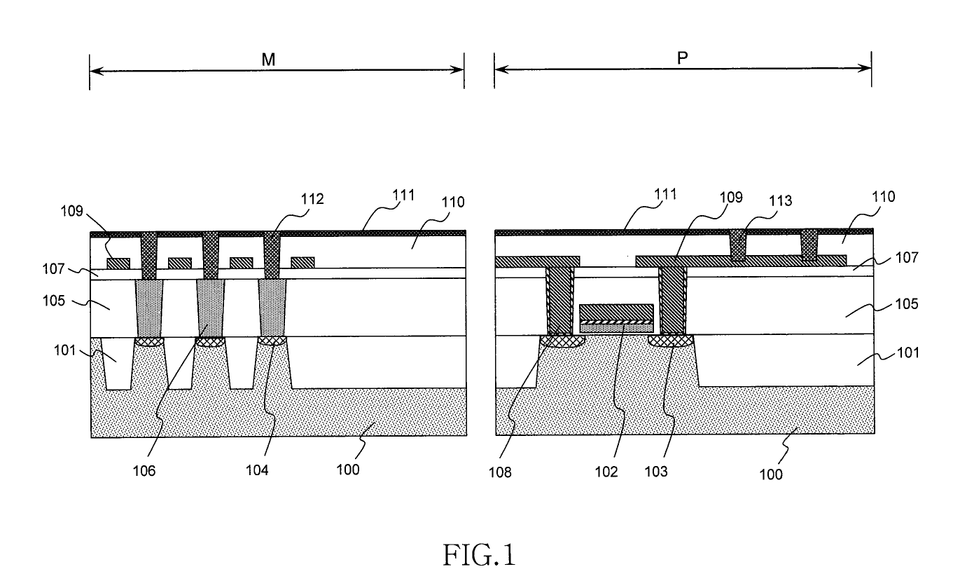

The surface of a semiconductor device (DRAM) according to embodiments of the present invention is divided into a “memory cell area” in which many memory cells are disposed, and a “peripheral circuit area” in which a peripheral circuit such as a decoder is disposed. Cross-sectional diagrams (FIG. 1 and so on) used for explaining the embodiments show a partial cross section of a memory cell area “M” on the left side, and a partial cross section of a peripheral circuit area “P” on the right side of the drawings, respectively.

A first embodiment of the present invention will be explained first. According to the first embodiment, plural capacitor layers are laminated, and a plate electrode included in the memory cell area and contact plugs included in the peripheral circuit area are formed simultaneously. A method of manufacturing a semiconductor device according to the first embodiment will be explained in detail below with reference to FIG. 1 to FIG. 20.

As shown in FIG. 1, an element isolation area 101 made of a silicon oxide film is formed according to a shallow trench isolation (STI) method. Next, transistors are formed in a memory cell area M and a peripheral circuit area P, respectively. Although not particularly limited, in the present embodiment, a gate 102 of the transistor is constituted by a laminated film including a polysilicon film, a tungsten nitride (WN) film, and a tungsten (W) film. In the memory cell area M shown in FIG. 1, a gate electrode is not shown, because the diagram shows a cross section along an extension direction of a word line. Diffusion layers 104, each of which is one of two diffusion layers (source/drain layers) of each memory cell transistor, are shown in FIG. 1.

Next, an inter-layer insulating film 105 is formed on the whole surface, and then, contact plugs 106 to be connected to the diffusion layers 104 in the memory cell area M are formed. Polysilicon can be used for the material of the contact plug 106. Next, an inter-layer insulating film 107 is formed on the whole surface, and then, contact plugs 108 to be connected to diffusion layers 103 in the peripheral circuit area P are formed. A laminate of TiN and tungsten can be used for the contact plugs 108. A tungsten film is then formed on the whole surface, and the tungsten film is patterned to form wiring layer 109. The wiring layer 109 is used as bit lines in the memory cell area M. While some of the contact plugs 108 are not shown in the memory cell area M, the some of the contact plugs 108 are also formed on the contact plug 106 formed on the other diffusion layers of the memory cell transistors, and are connected to the wiring layers 109 as the bit lines, respectively.

Next, after a silicon oxide film 110 and a silicon nitride film 111 are formed on the whole surface, contact plugs 112 are formed in the memory cell area M, and contact plugs 113 are formed in the peripheral circuit area P. The contact plugs 112 need to be connected to the contact plugs 106, respectively, and the contact plugs 113 need to be connected to the wiring layer 109. Tungsten (W) can be used for the material of the contact plugs 112 and 113. As a result, the structure shown in FIG. 1 is obtained.

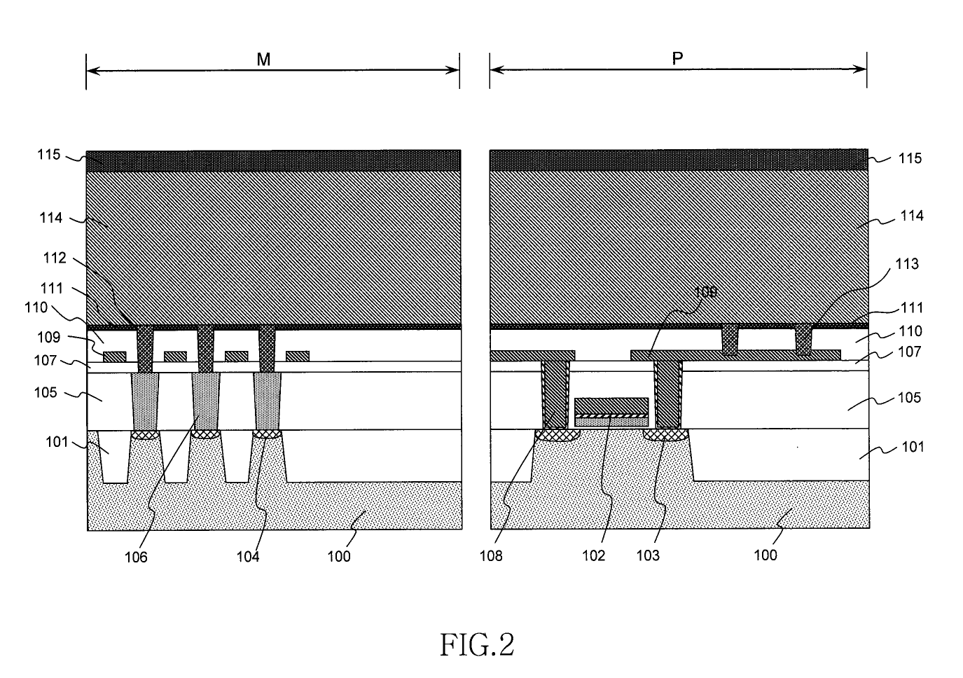

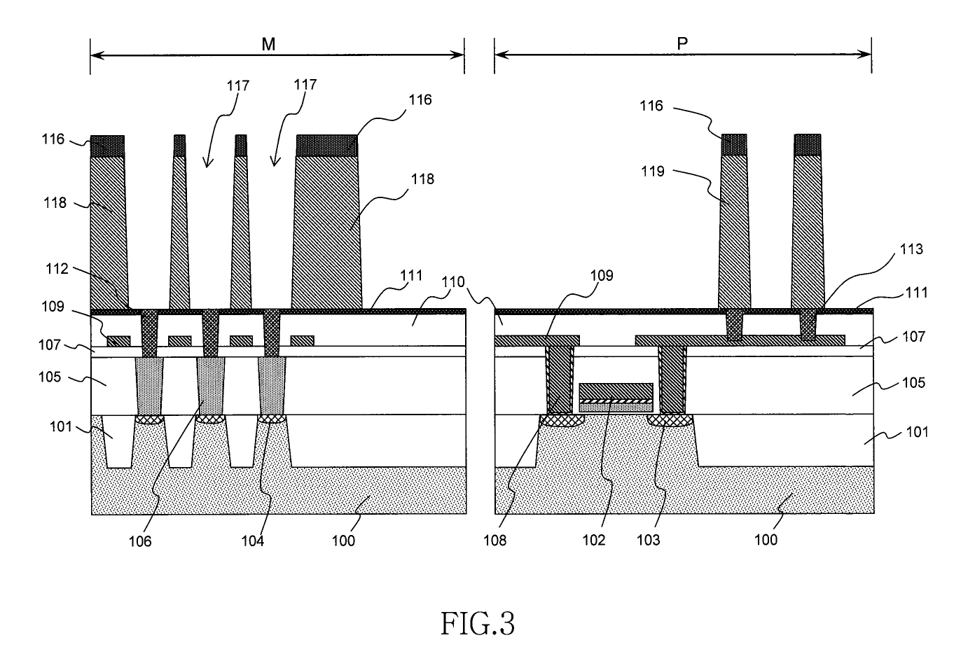

As shown in FIG. 2, a tungsten film 114 with a thickness of about 1,000 nm is formed on the whole surface. Then, a silicon nitride film 115 with a thickness of about 200 nm is formed on the tungsten film 114. The silicon nitride film 115 is patterned using a mask (not shown), according to a lithography technique, thereby forming a cap insulating layer 116 as shown in FIG. 3. Further, the tungsten film 114 (refer to FIG. 2) is patterned, thereby forming a plate electrode 118 in the memory cell area M and forming contact plugs 119 in the peripheral circuit area P. The plate electrode 118 is formed to be kept away from the plural contact plugs 112. As a result, the upper surfaces of the contact plugs 112 are exposed to openings 117. When the etching control of patterning the tungsten film 114 (forming the plate electrode 118) is poor and also when the contact plug 112 at the bottom of each of the openings 117 collapse greatly, it is preferable to form a stopper insulating film in advance on the contact plugs 112. On the other hand, the contact plugs 119 are formed on the contact plugs 113, so that the contact plugs 119 are connected to the contact plug 113, respectively. The plate electrode 118 is a large electrode that is provided in common to plural memory cell transistors. While the plate electrode 118 is disconnected in the present cross-sectional diagram, the plate electrode 118 is continuous in other cross section.

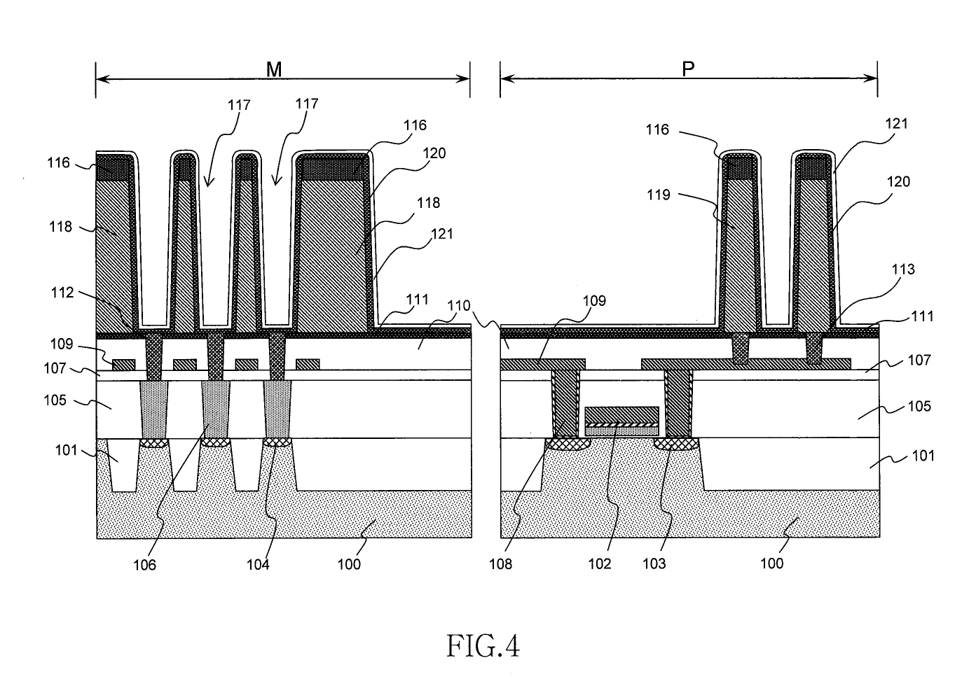

Next, as shown in FIG. 4, a tantalum oxide (Ta₂O₅) film 120 with a thickness of about 5 nm to be capacity insulating films of the capacitors is formed on the whole surface, according to an atomic layer deposition (ALD) method. Further, a silicon oxide film 121 with a thickness of about 5 nm is formed to protect the tantalum oxide film 120. With this arrangement, the surface of the plate electrode 118 and the surface of the contact plugs 119 are covered with the tantalum oxide film 120 and the silicon oxide film 121, respectively.

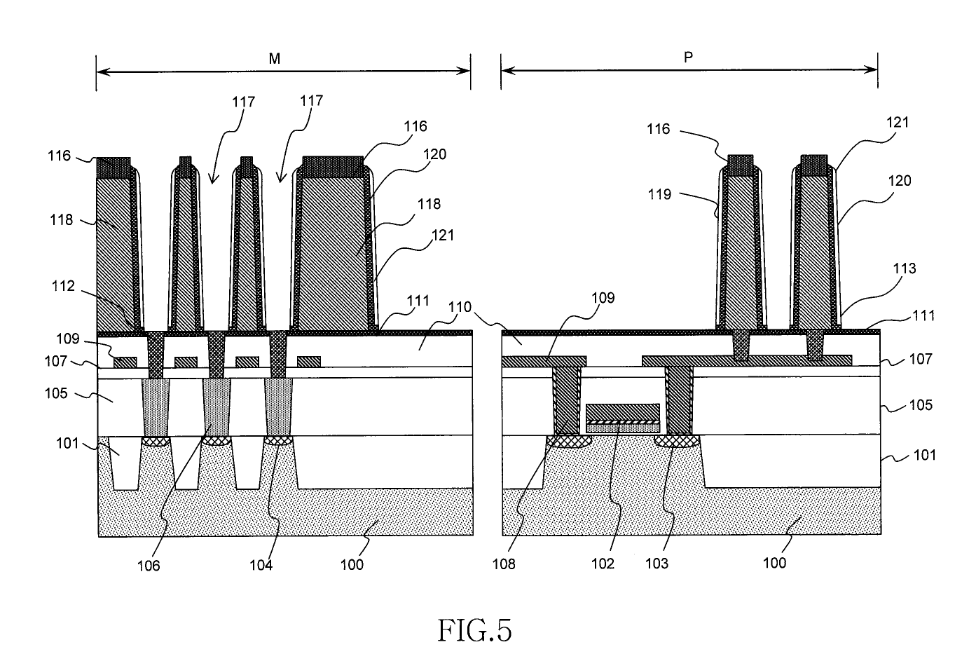

Next, as shown in FIG. 5, the whole surface of the silicon oxide film 121 is etched back, and then, the whole surface of the tantalum oxide film 120 is etched back. Based on this etch back, the silicon oxide film 121 and the tantalum oxide film 120 that are formed in the area parallel with the silicon substrate 100 are removed. Therefore, the upper surface of the contact plug 112 is exposed at each bottom of the openings 117. On the other hand, the silicon oxide film 121 and the tantalum oxide film 120 that are formed in the area substantially perpendicular to the silicon substrate 100 are not removed. As a result, the tantalum oxide film 120 and the silicon oxide film 121 remain in the sidewalls of the plate electrode 118 and the sidewalls of the contact plugs 119. In the present embodiment, the surface of the tantalum oxide film 120 is covered with the silicon oxide film 121. Therefore, when the tantalum oxide film 120 is etched back, the presence of the silicon oxide film 121 restricts the etching damage applied on the tantalum oxide film 120.

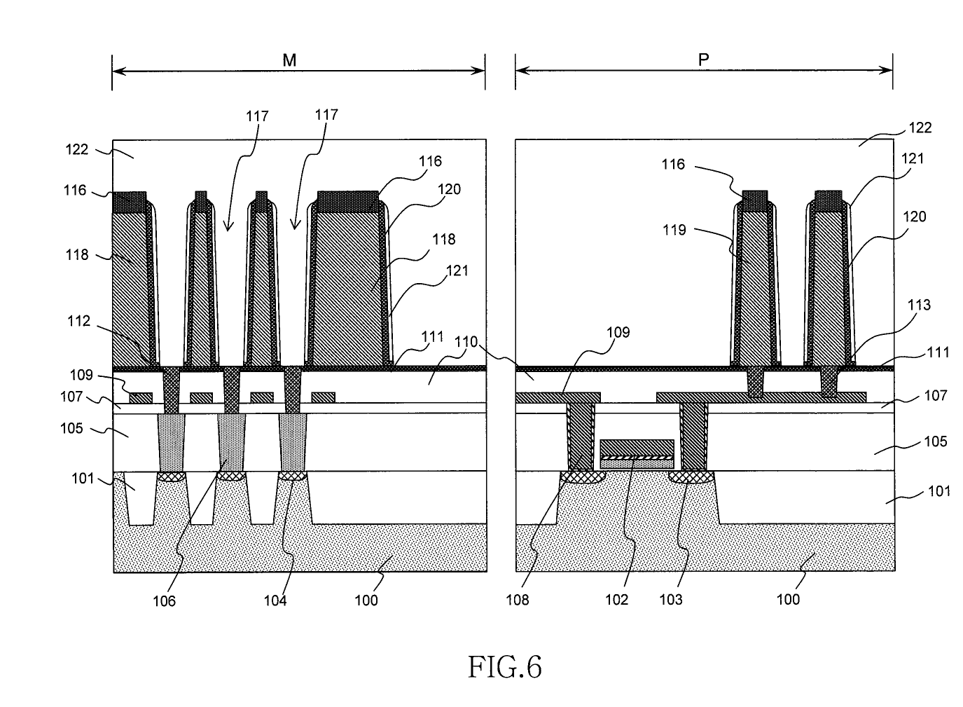

Next, as shown in FIG. 6, a silicon oxide film 122 with a large thickness is formed on the whole surface so as to fill the gap between the openings 117 and the contact plugs 119. Thereafter, the silicon oxide film 122 is flattened by a chemical mechanical polishing (CMP) method. While the silicon oxide film 122 is kept remaining on the cap insulating layer 116 in FIG. 6, when the control by the CMP method is sufficient, the cap insulating layer 116 can be exposed as a stopper film according to the CMP method.

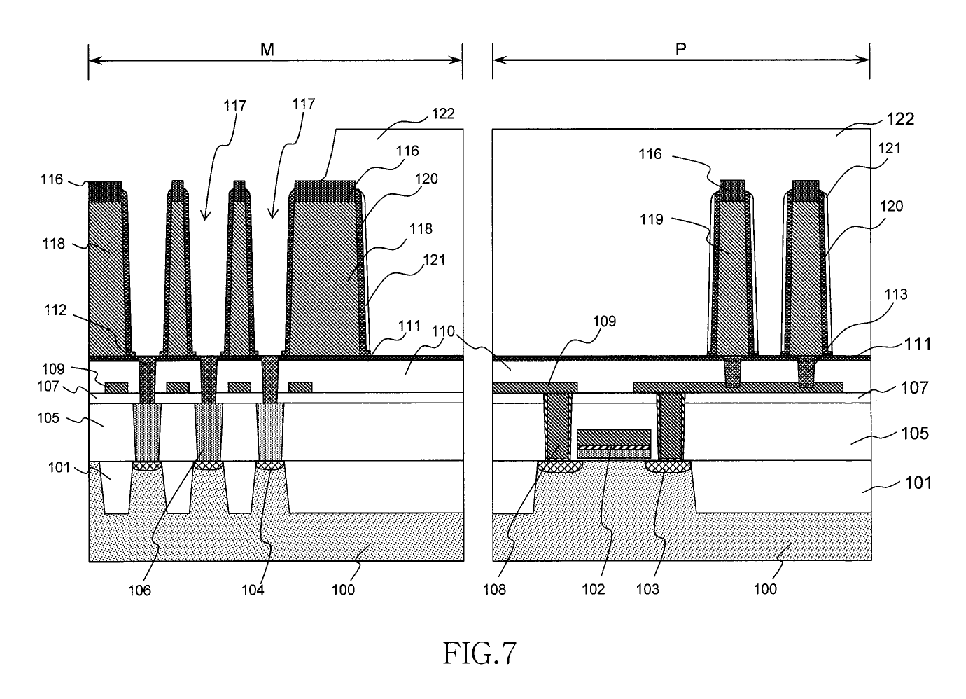

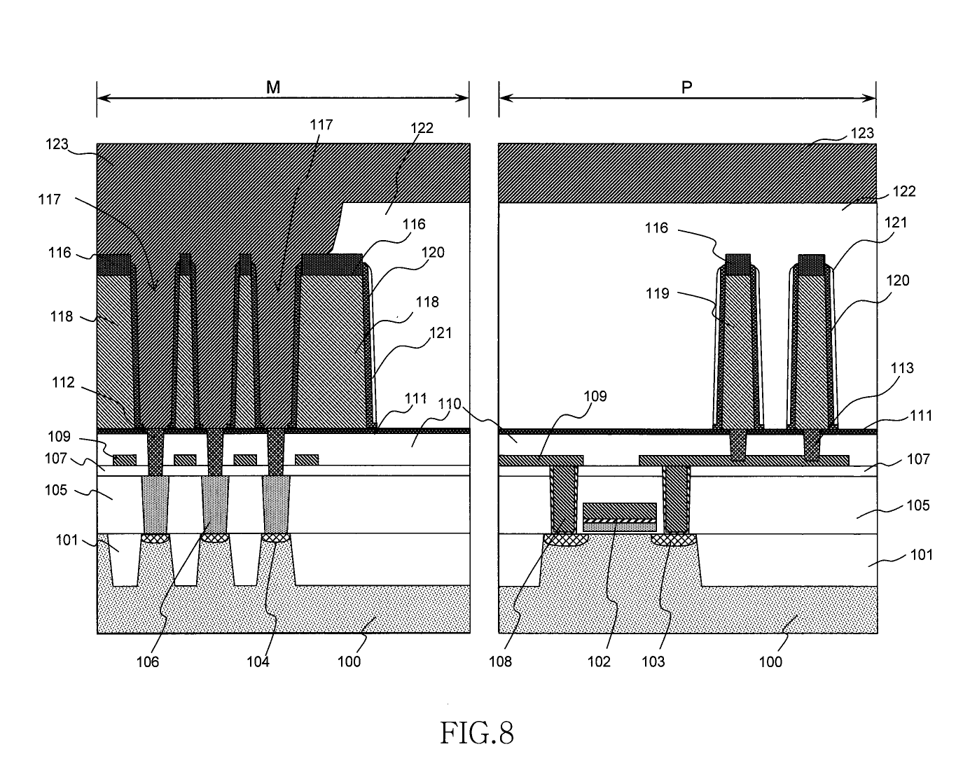

Next, as shown in FIG. 7, whole of the peripheral circuit area P is covered with a mask layer (not shown), and wet etching is performed to selectively remove the silicon oxide film 122 and the silicon oxide film 121 in the memory cell area M. As a result, the openings 117 are formed again. As shown in FIG. 8, a tungsten film 123 is formed on the whole surface to fill the openings 117.

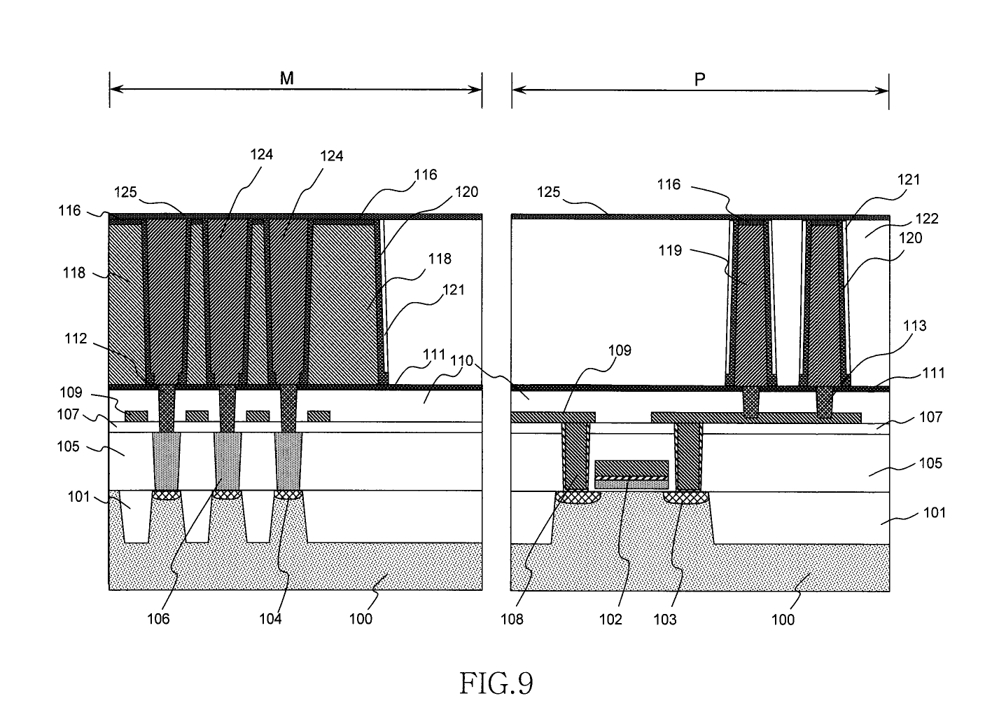

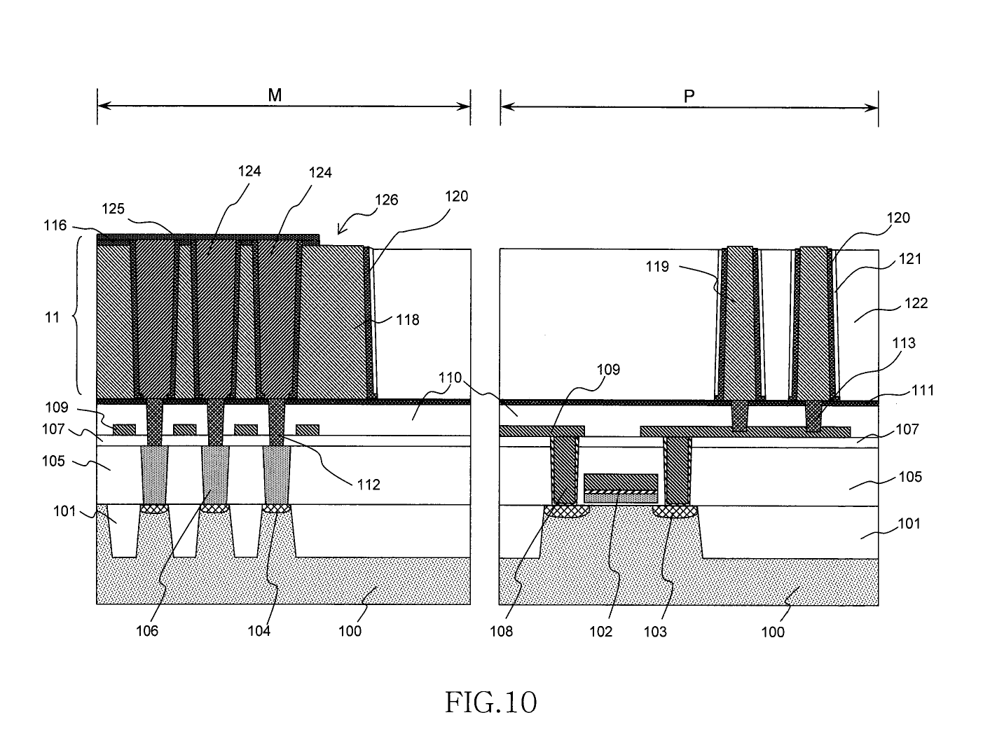

Next, the tungsten film 123 and the silicon oxide film 122 are polished by the CMP method, using the cap insulating layer 116 as a stopper. In this process, storage electrodes 124 of the capacitors embedded in the openings 117 are formed as shown in FIG. 9. Next, a silicon nitride film 125 with a thickness of about 100 nm is formed on the whole surface. Thereafter, as shown in FIG. 10, the area excluding a connection part 126 on the plate electrode 118 in the memory cell area M is covered with a mask layer (not shown). In this state, the silicon nitride film 125 and the cap insulating layer 116 are etched.

In the above process, a first capacitor layer 11 including the storage electrodes 124, the tantalum oxide films (capacity insulating films) 120, and the plate electrode 118 is formed in the memory cell area M. At the same time, the contact plugs 119 are formed in the peripheral circuit area P. Thereafter, a second capacitor layer, a third capacitor layer, and so on are formed sequentially. A manufacturing process of the second capacitor layer will be explained next.

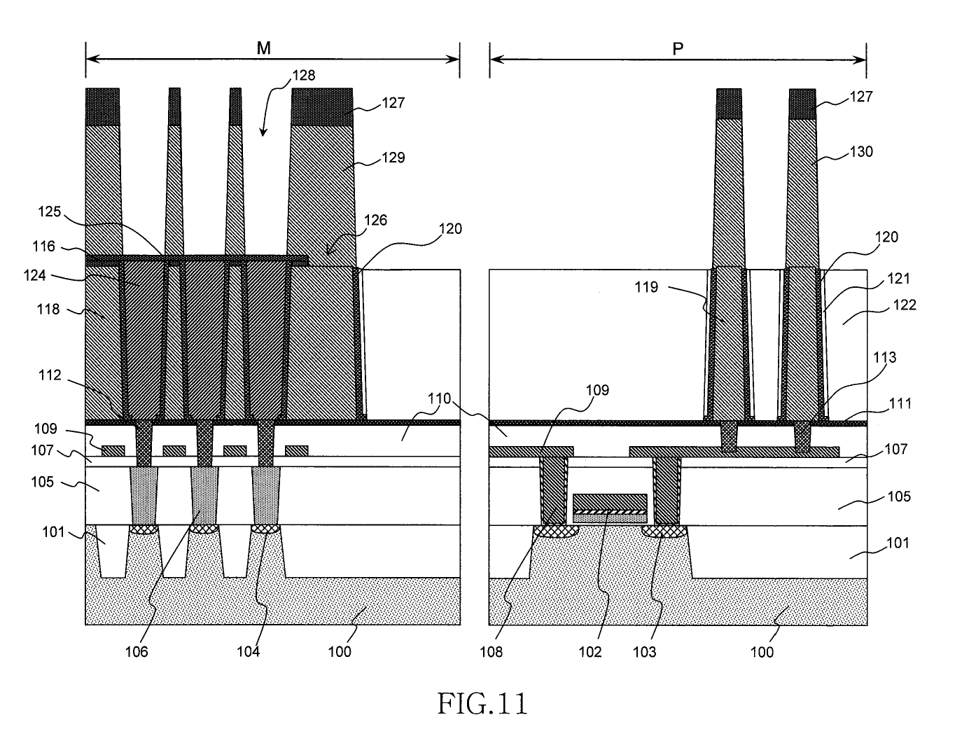

FIG. 11 to FIG. 19 show the manufacturing process of the second capacitor layer.

As shown in FIG. 11, a tungsten film with a thickness of about 1,000 nm is formed on the whole surface, and then a silicon nitride film with a thickness of about 200 nm is formed, in the similar process as that shown in FIG. 2 and FIG. 3. Next, the silicon nitride film is patterned to form a cap insulating layer 127 according to the lithographic technique. Further, the tungsten film is patterned to form a plate electrode 129 in the memory cell area M. Contact plugs 130 are formed in the peripheral circuit area P.

As shown in FIG. 11, planar positions of openings 128 as areas in which the plate electrode 129 is not formed corresponds to planar positions of the storage electrodes 124, respectively. The silicon nitride film 125 is exposed at the bottom of the openings 128. In the process shown in FIG. 10, since the connection part 126 on the upper surface of the plate electrode 118 is exposed, the plate electrode 118 and the plate electrode 129 are short-circuited via this connection part 126. In the peripheral circuit area P, the contact plugs 130 and the contact plugs 119 are short-circuited, respectively.

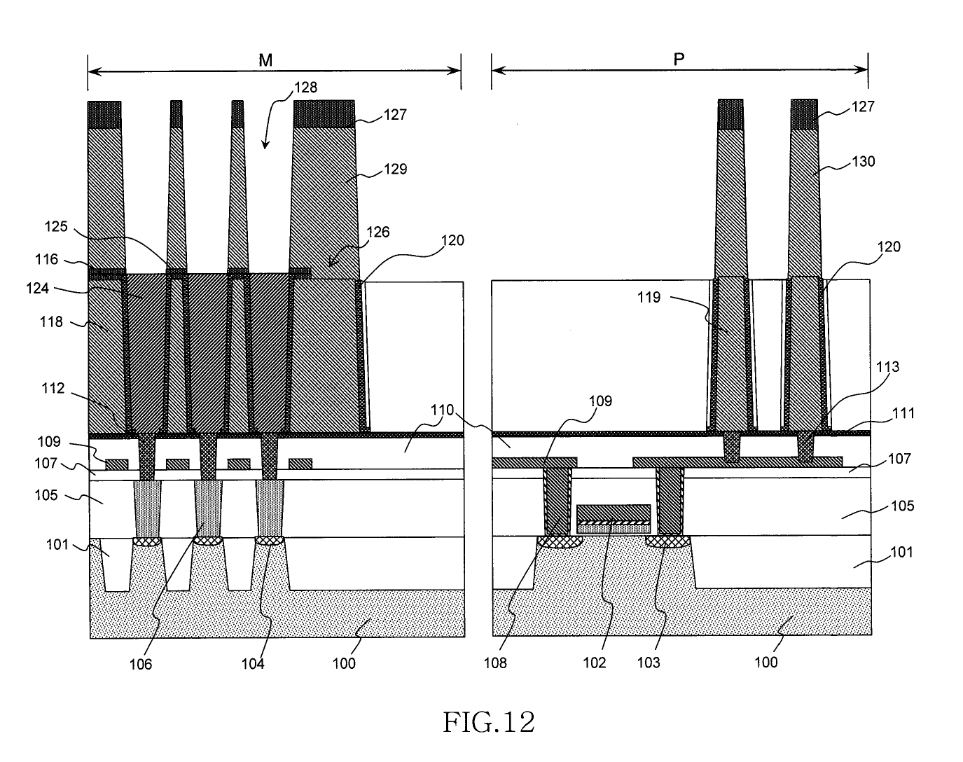

Next, as shown in FIG. 12, the silicon nitride film 125 exposed at the bottom of the openings 128 is removed by etch back, thereby exposing the upper surfaces of the storage electrodes 124.

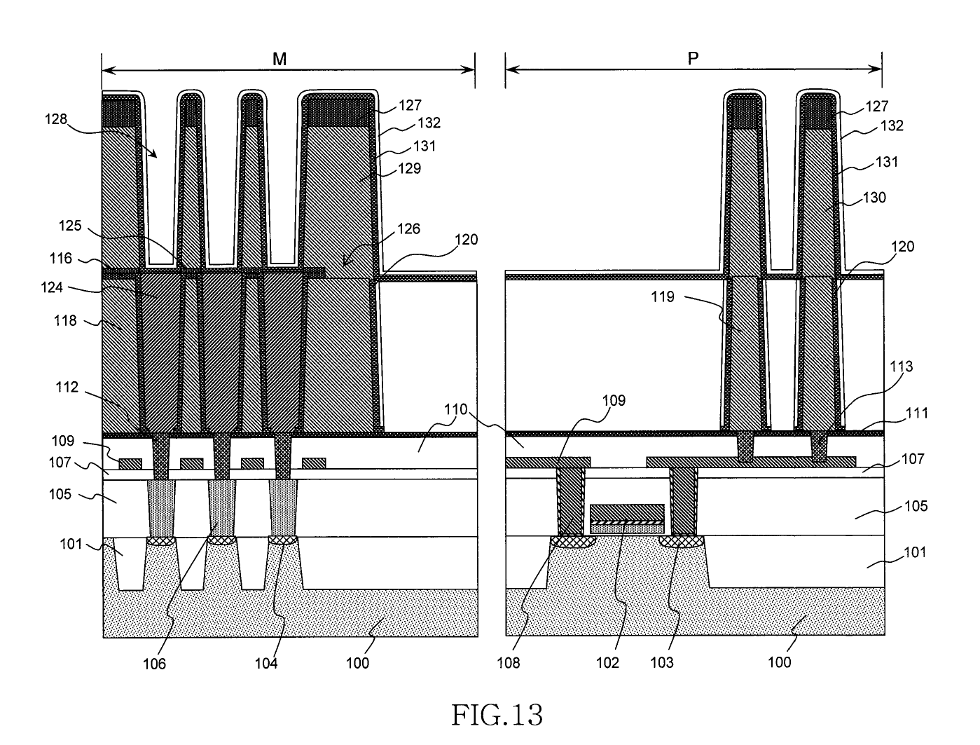

Next, as shown in FIG. 13, a tantalum oxide (Ta₂O₅) film 131 with a thickness of about 5 nm to be capacity insulating films of the capacitors is formed on the whole surface, and a silicon oxide film 132 with a thickness of about 5 nm is formed to protect the tantalum oxide film 131, without removing the cap insulating layer 127 used as a mask, similarly to the process shown in FIG. 4.

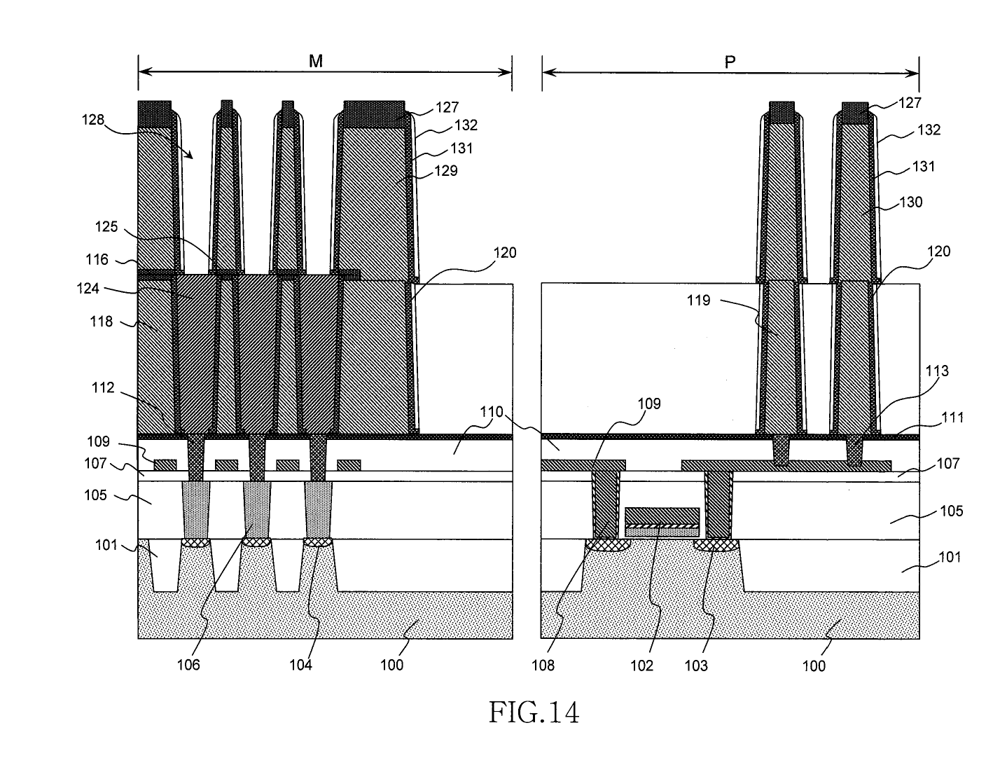

Next, as shown in FIG. 14, the whole surface is etched back, and the upper surfaces of the storage electrodes 124 are exposed at the bottom of the openings 128, similarly to the process shown in FIG. 5. On the other hand, the tantalum oxide film 131 and the silicon oxide film 132 are kept remaining in the sidewalls of the plate electrode 129 and the sidewalls of the contact plug 130, respectively.

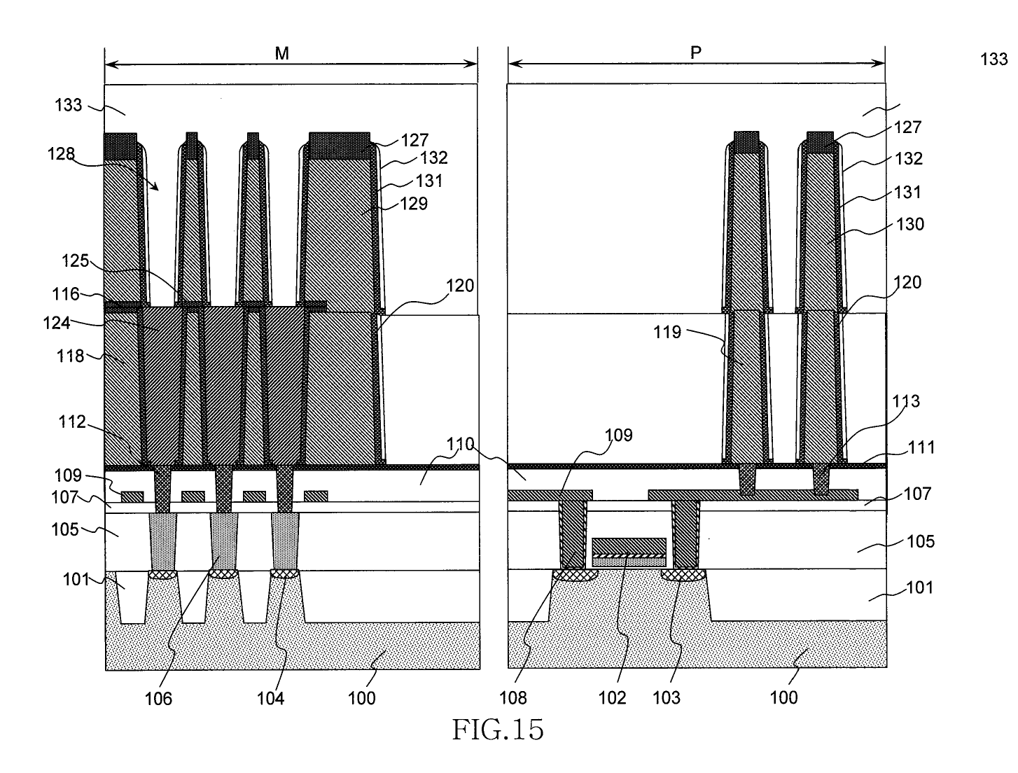

Next, a silicon oxide film 133 with a large thickness is formed on the whole surface to fill the gap between the openings 128 and the plural contact plugs 130, as shown in FIG. 15. Thereafter, the silicon oxide film 133 is flattened by the CMP method, similarly to the process shown in FIG. 6.

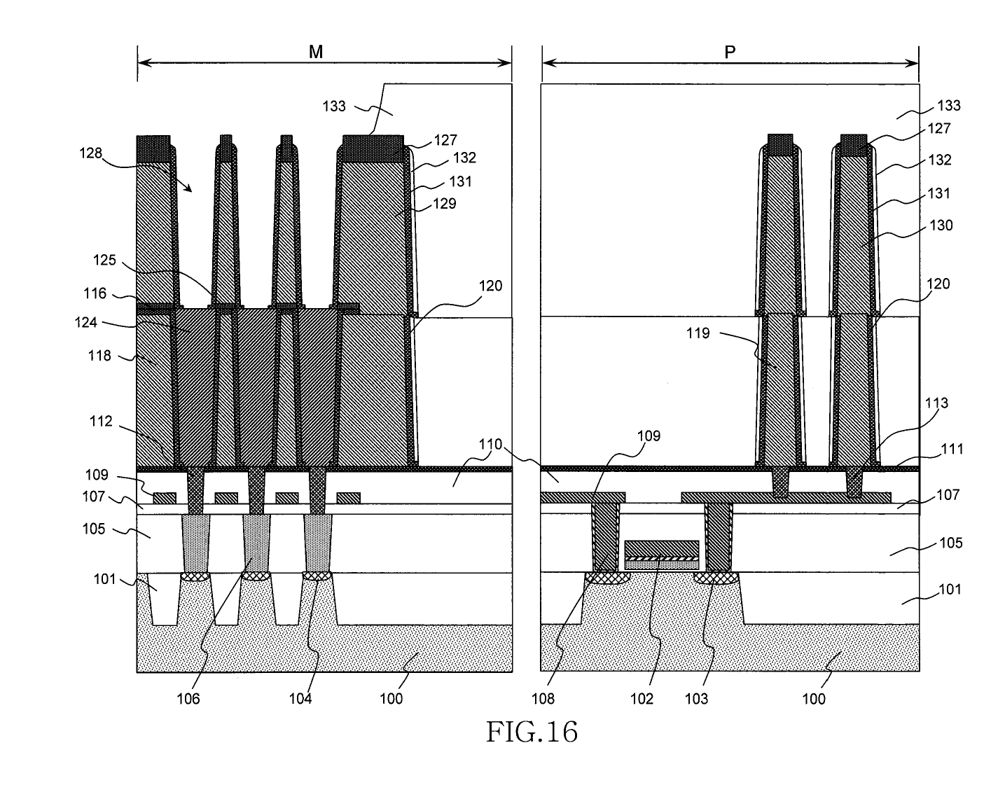

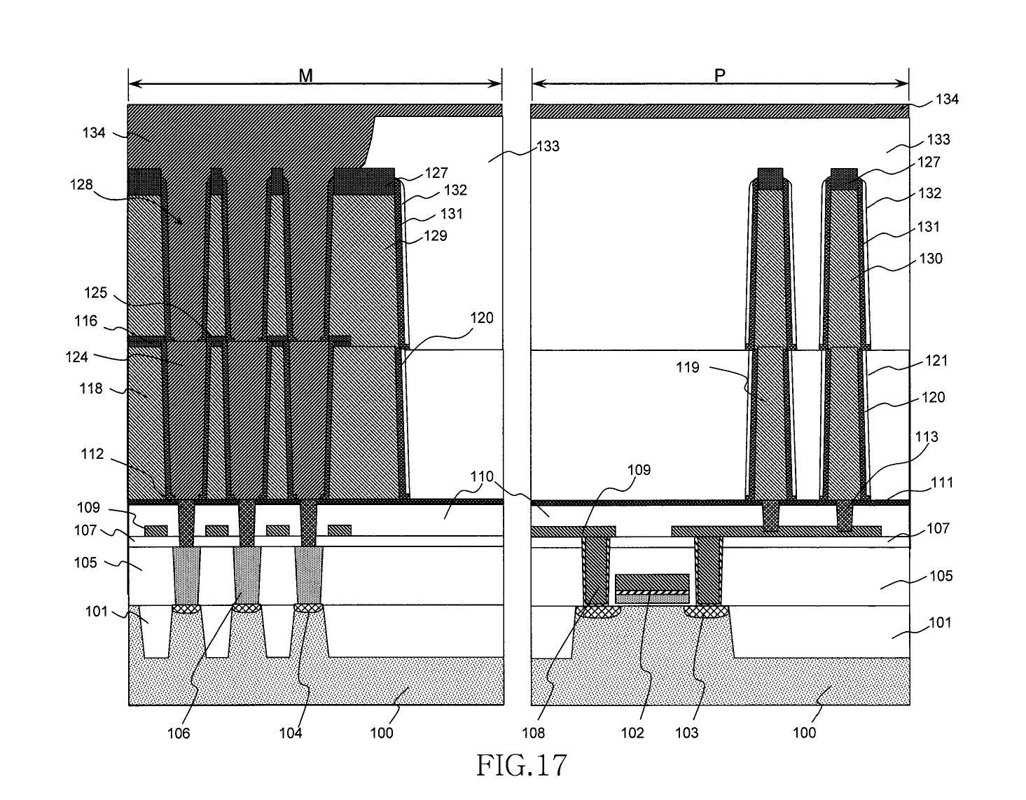

Next, as shown in FIG. 16, the peripheral circuit area P is covered with a mask layer (not shown), and a wet etching is performed to selectively remove the silicon oxide film 133 in the memory cell area M and the silicon oxide film 132 within the opening 128, similarly to the process shown in FIG. 7. As a result, the openings 128 are formed again. Then, as shown in FIG. 17, a tungsten film 134 is formed on the whole surface to fill the openings 128, similarly to the process shown in FIG. 8.

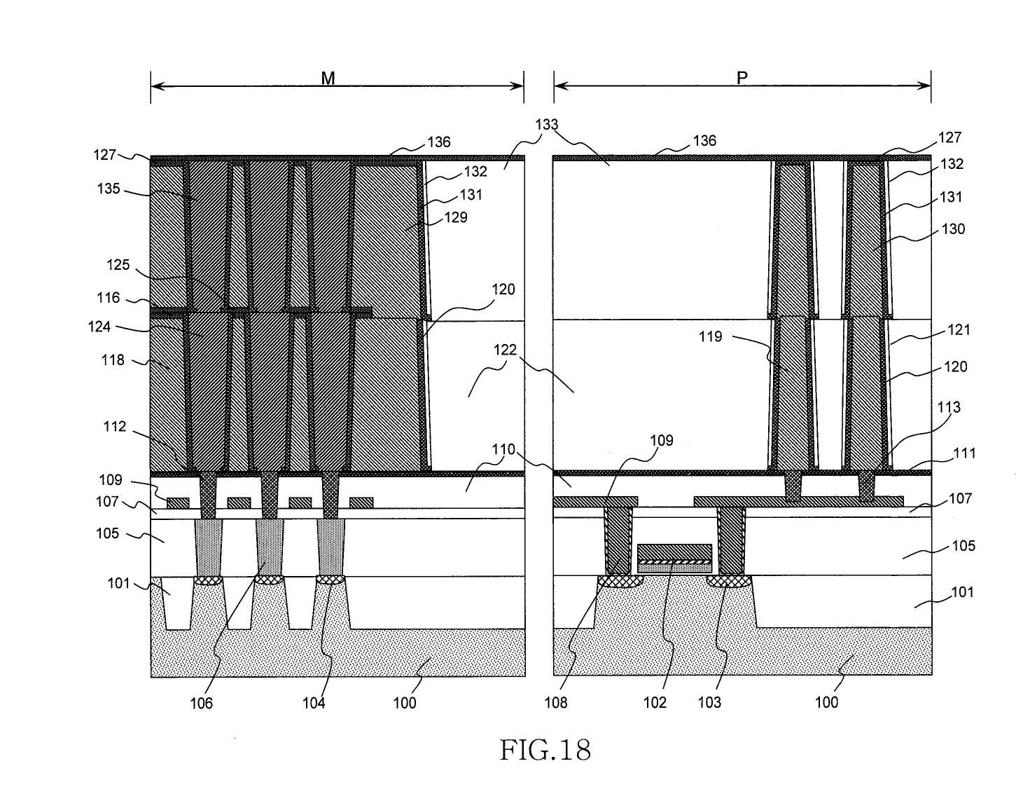

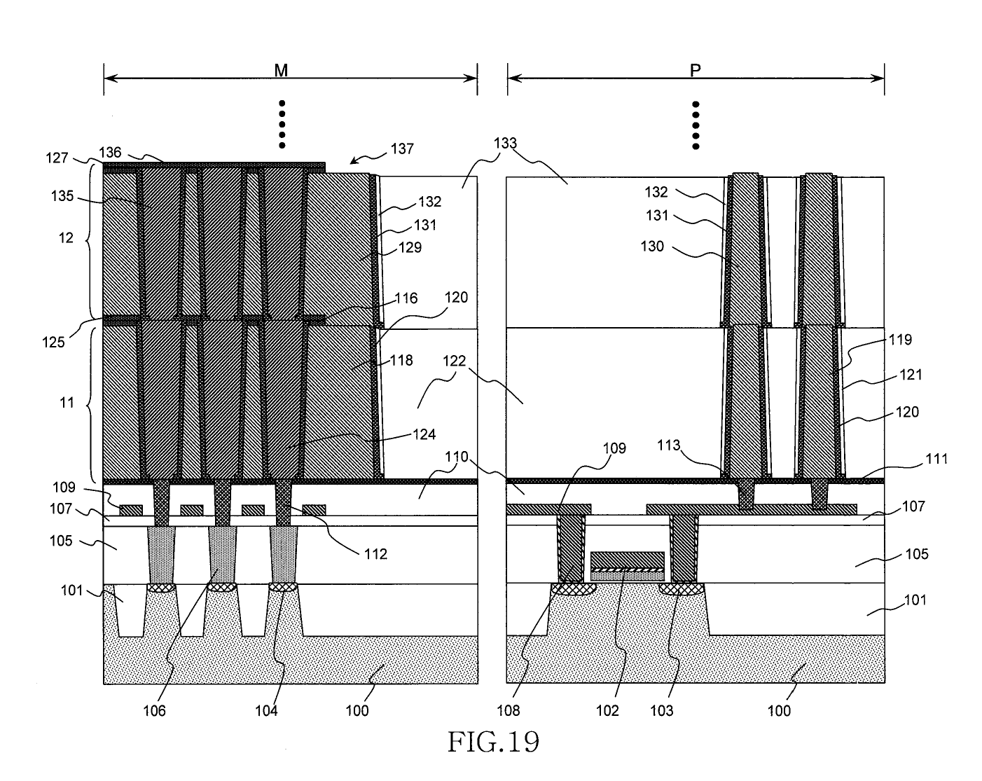

Next, as shown in FIG. 18 the tungsten film 134 and the silicon oxide film 133 are removed by the CMP method, using the cap insulating layer 127 as a stopper, similarly to the process shown in FIG. 9. Through this process, storage electrodes 135 embedded in the openings 128 are formed. Next, a silicon nitride film 136 with a thickness of about 100 nm is formed on the whole surface. Next, as shown in FIG. 19, the area excluding a connection part 137 on the plate electrode 129 in the memory cell area M is covered with a mask layer (not shown), similarly to the process shown in FIG. 10. In this state, the silicon nitride film 136 and the cap insulating layer 127 are etched.

Through the above process, a second capacitor layer 12 including the storage electrodes 135, the tantalum oxide films (capacity insulating films) 131, and the plate electrode 129 is formed in the memory cell area M. The exposed connection part 137 of the plate electrode 129 becomes a part with which a plate electrode of a third capacitor layer to be formed on the connection part 137 is connected.

Thereafter, a process similar to that shown in FIG. 11 to FIG. 19 is repeated, thereby laminating capacitor layers in a number (n layers) enough to obtain necessary electrostatic capacity.

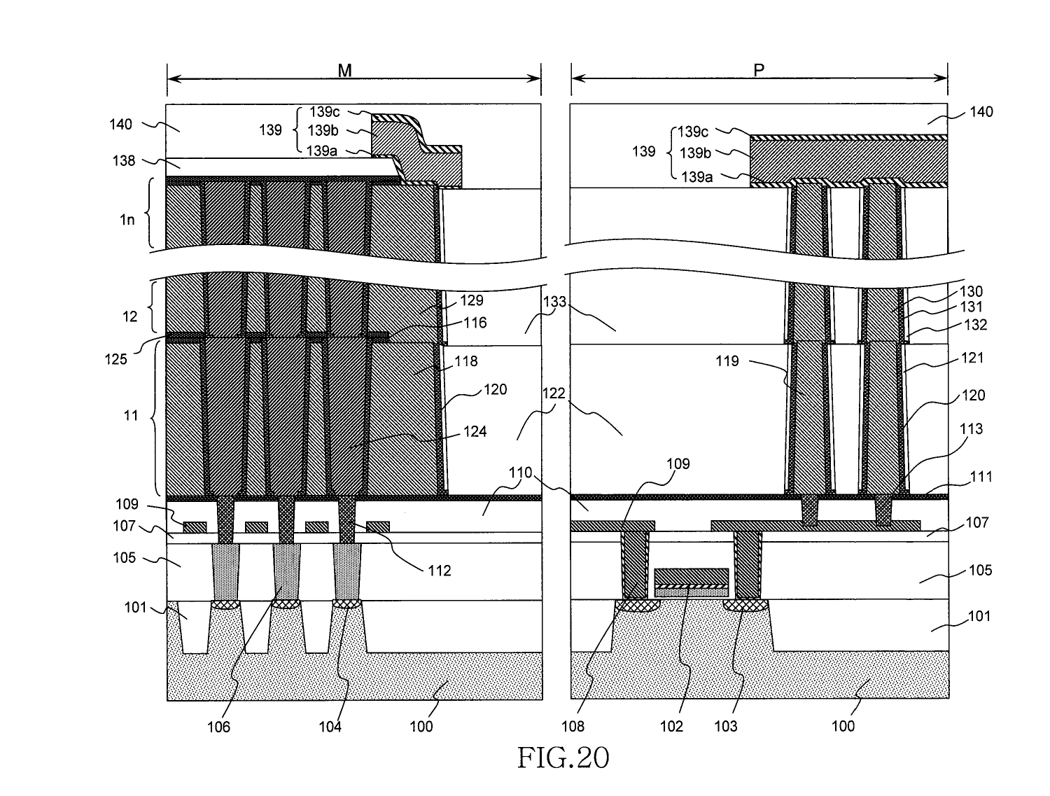

Then, as shown in FIG. 20, an inter-layer insulating film 138 is formed on the top capacitor layer 1n in the memory cell area M, and thereafter, a TiN/Ti film 139a, an AlCu film 139b, and a TiN film 139c are laminated on the whole surface. The laminated film is patterned to form a wiring layer 139. Then, an insulating film 140 is formed to cover the wiring layer 139. Further, wiring connection plugs and upper layer wirings (not shown) are formed by a necessary number, respectively. Lastly, a protection film is formed on the top wiring layer, and a connection hole from which an electrode pad is exposed is formed in the protection film.

Based on the above process, plural capacitor layers are laminated in the memory cell area M, and plural contact plugs are laminated in the peripheral circuit area P, thereby completing a DRAM.

As explained above, in the present embodiment, plural capacitor layers having substantially the same structure are repeatedly formed. Therefore, the aspect ratio in each capacitor layer can be restricted. Consequently, a very large electrostatic capacity can be obtained while securing high yield. Since the plate electrode in the memory cell area and the contact plugs in the peripheral circuit area are simultaneously formed using the same material in the capacitor layer, increase in the number of manufacturing steps can be suppressed, and increase in the manufacturing cost can be minimized. Further, because the capacitor layers are formed in substantially the similar process, the same manufacturing equipment can be repeatedly used to form plural capacitor layers. Consequently, increase in the manufacturing cost can be minimized.

A pattern formed by lithography is usually narrower than a desired pattern. However, in the present embodiment, the plate electrode is formed before the storage electrodes by lithography. Therefore, even when the pattern of the plate electrode is narrower than the desired pattern, the surface area of the storage electrode formed thereafter is not made smaller, and is rather increased. In other words, even when the pattern shape of the plate electrode varies due to the variation in the lithography condition, this variation works to increase the electrostatic capacity, as compared with a storage electrode of island-shape pattern which is independently formed beforehand as in the conventional process. Therefore, a possibility of a capacity shortage can be reduced.

Since the cap insulating layer is formed on the plate electrode after the plate electrode is formed, the storage electrode in the lower layer and the storage electrode in the upper layer can be connected in self alignment. In other words, in the process shown in FIG. 11, while the opening 128 is aligned to be formed right above the storage electrode 124, there is a possibility that a part of the opening 128 is formed across the plate electrode due to a misalignment. Since the cap insulating layer 116 is formed on the plate electrode 118, even when the misalignment occurs, the plate electrode 118 is not exposed if the etching ends at the point of time when the upper surface of the storage electrode 124 is exposed after removing the silicon nitride film 125. Therefore, the plate electrode 118 in the lower layer is not short-circuited with the storage electrode 135 of the capacitor in the upper layer.

The conductive film is patterned by lithography to first form the plate electrode having the opening, and then the storage electrode is formed to be embedded in the opening of the plate electrode. Therefore, the cross section of the storage electrode becomes smaller toward the substrate. In other words, the planar dimension of the lower surface becomes smaller than the planar dimension of the upper surface. This size difference of the dimensions becomes margin of the misalignment, and can effectively prevent the short-circuiting between the plate electrode in the lower layer and the storage electrode in the upper layer.

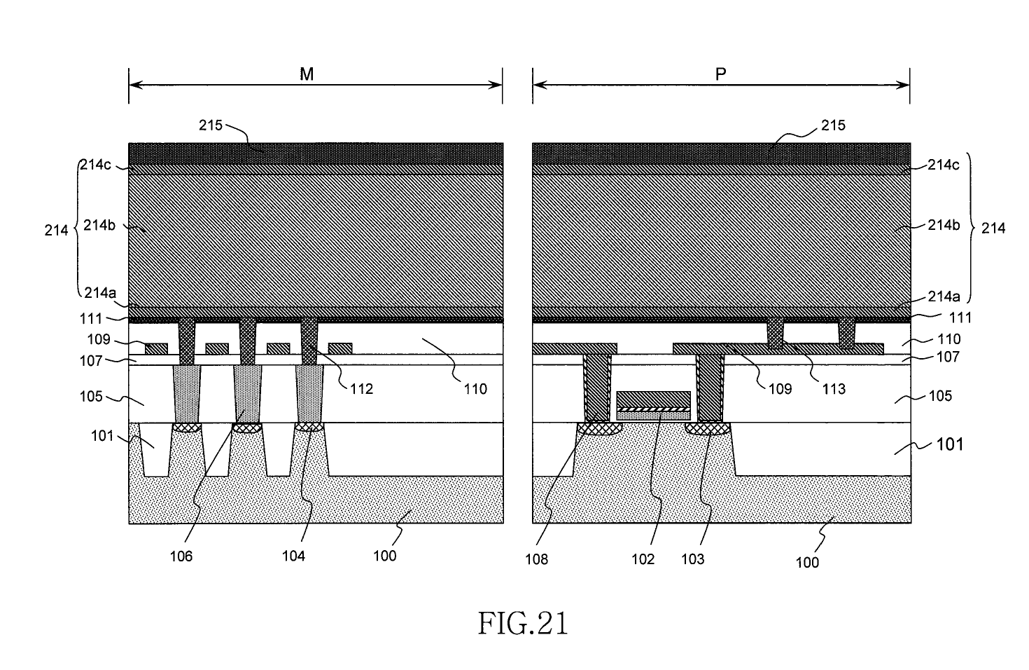

A second embodiment of the present invention will be explained next. The second embodiment is the same as the first embodiment in that plural capacitor layers are laminated. The second embodiment is different from the first embodiment in that the plate electrode included in the memory cell area and the wiring layer included in the peripheral circuit area are formed simultaneously. A method of manufacturing a semiconductor device according to the second embodiment will be explained in detail below with reference to FIG. 21 to FIG. 35.

The manufacturing process up to the process shown in FIG. 1 according to the first embodiment is similar to the corresponding process according to the second embodiment. Therefore, a redundant explanation will be omitted.

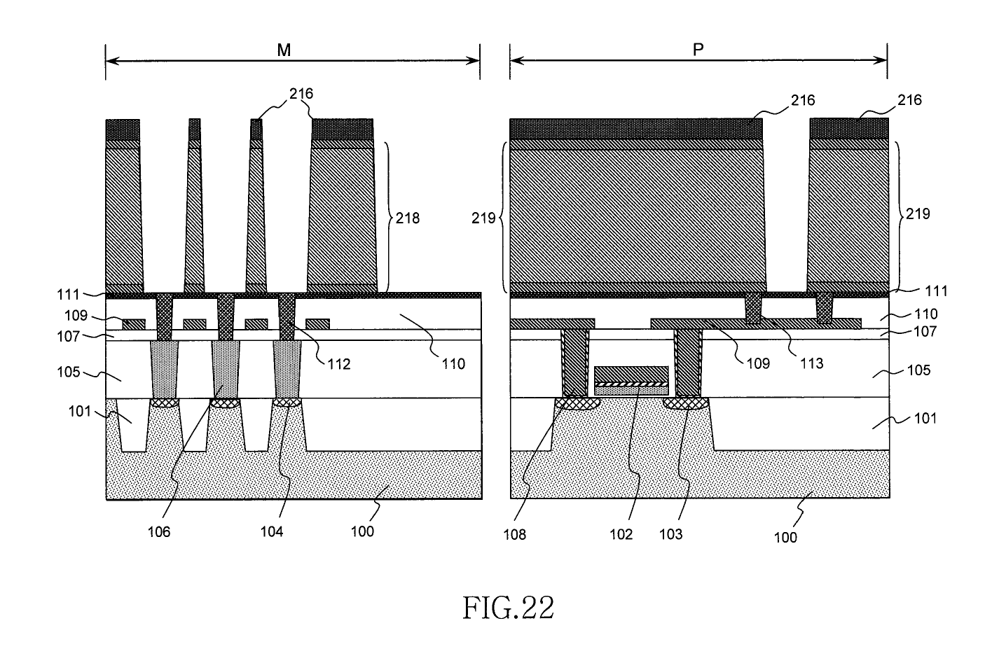

Following the process shown in FIG. 1, a conductive film 214 is formed on the whole surface, and a silicon nitride film 215 with a thickness of about 200 nm is formed on the conductive film 214, as shown in FIG. 21. The conductive film 214 includes a Ti/TiN film 214a with a thickness of about 20 nm and about 30 nm respectively, an AlCu film 214b with a thickness of about 800 nm, and a TiN film 214c with a thickness of about 50 nm, laminated in this order. The silicon nitride film 215 is patterned using a mask (not shown) according to the lithography technique, thereby forming a cap insulating layer 216 as shown in FIG. 22. Further, the conductive film 214 (refer to FIG. 21) is patterned to form a plate electrode 218 in the memory cell area M, and a wiring layer 219 are formed in the peripheral circuit area P.

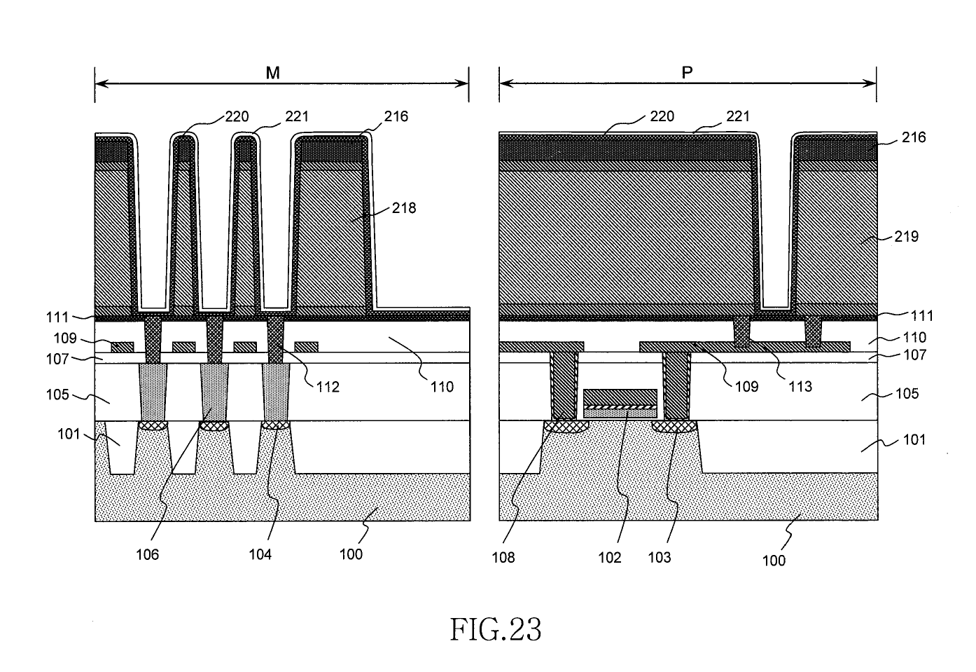

Next, as shown in FIG. 23, a tantalum oxide (Ta₂O₅) film 220 with a thickness of about 5 nm to be a capacity insulating film of the capacitor is formed on the whole surface, according to the ALD method. Further, a silicon oxide film 221 with a thickness of about 5 nm is formed to protect the tantalum oxide film 220.

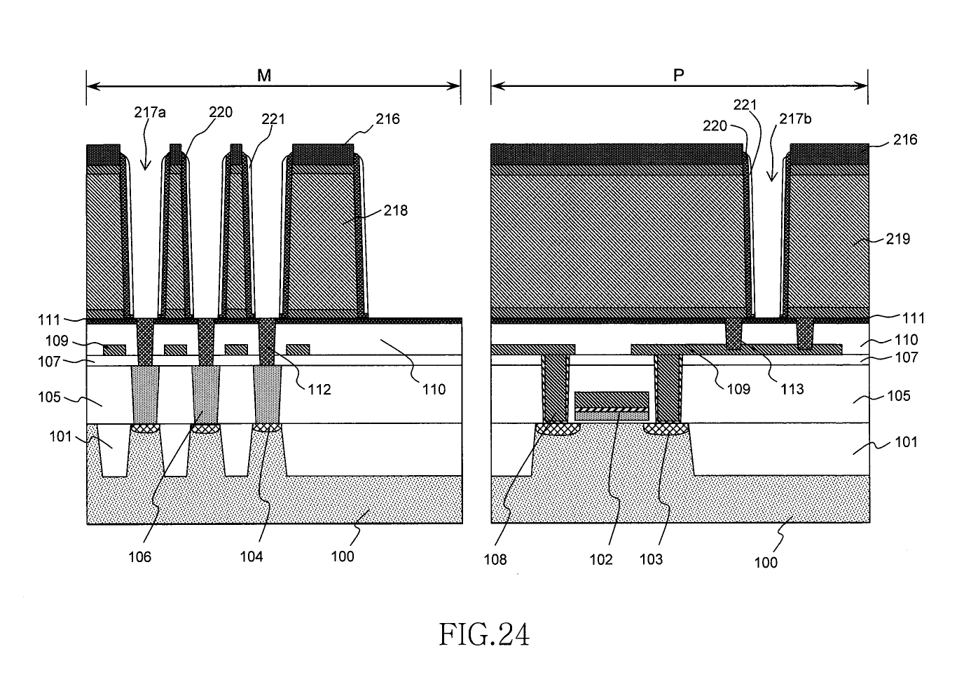

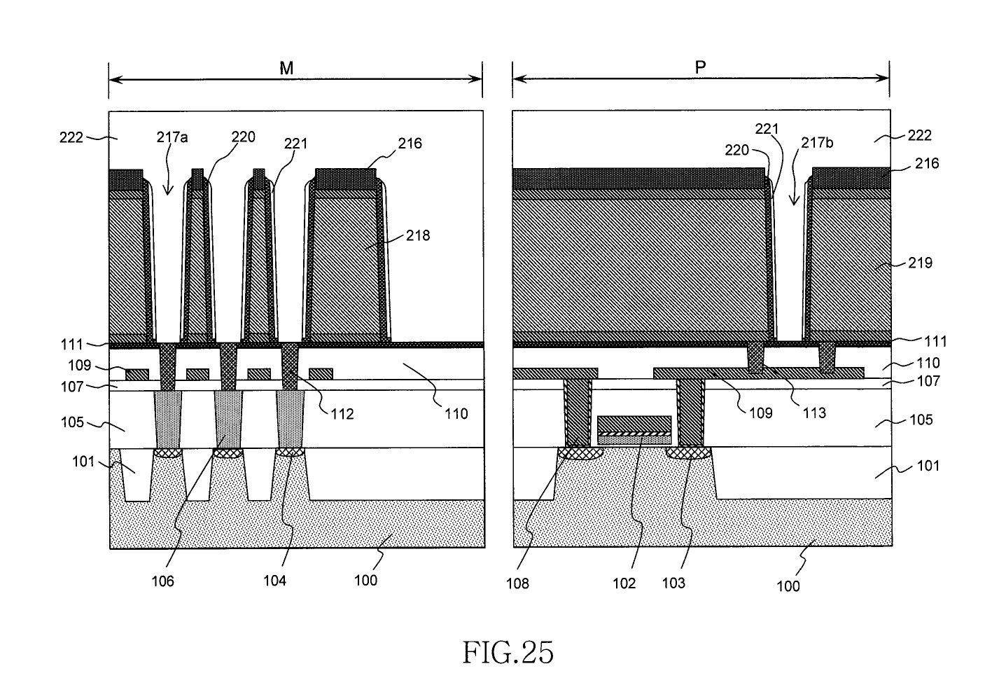

Next, as shown in FIG. 24, the whole surface of the silicon oxide film 221 is etched back, and then, the whole surface of the tantalum oxide film 220 is etched back. Based on this etch back, the upper surfaces of the contact plugs 112 are exposed at the bottoms of openings 217a. Next, as shown in FIG. 25, a silicon oxide film 222 with a large thickness is formed on the whole surface so as to fill the gap between the openings 217a and a wiring space 217b in the wiring layer 219. Thereafter, the silicon oxide film 222 is flattened by the CMP method. While the silicon oxide film 222 is kept remaining on the cap insulating layer 216 in FIG. 25 similarly to the first embodiment, when the control by the CMP method is sufficient, the cap insulating layer 216 can be exposed as a stopper film according to the CMP method.

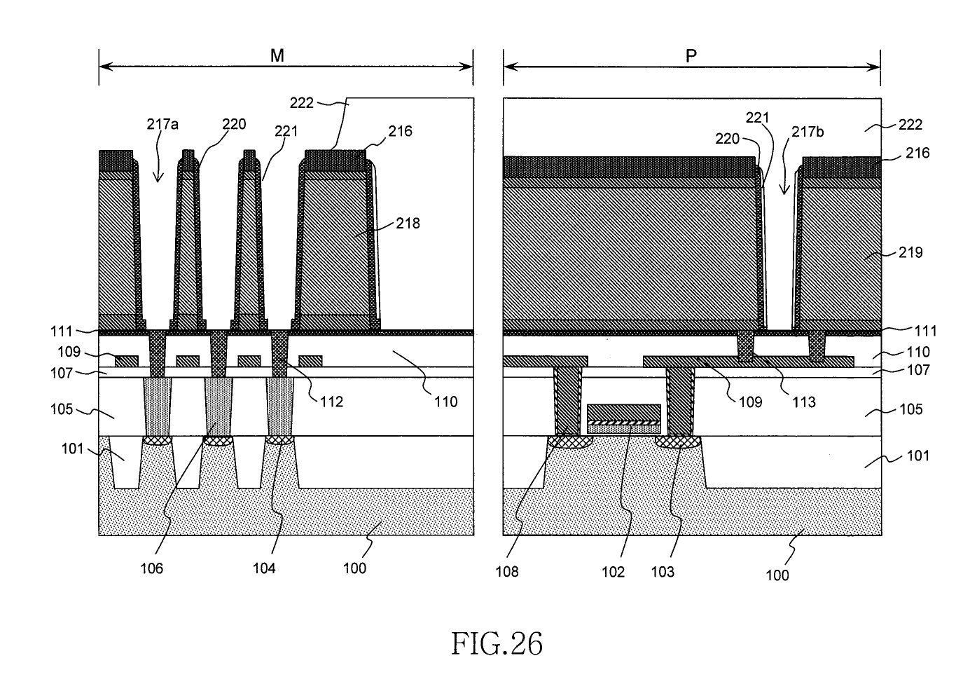

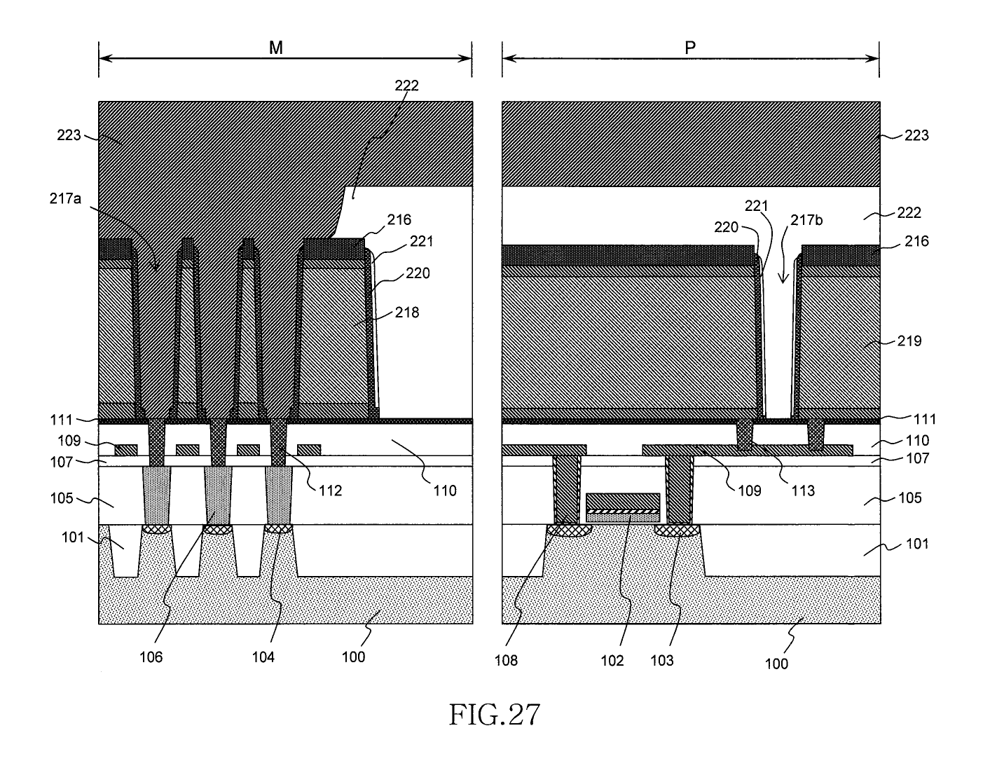

Next, as shown in FIG. 26, whole of the peripheral circuit area P is covered with a mask layer (not shown), and wet etching is performed so as to selectively remove and the silicon oxide film 222 and the silicon oxide film 221 in the openings 217a, thereby forming the openings 217a again. As shown in FIG. 27, a tungsten film 223 is formed on the whole surface to fill the openings 217a.

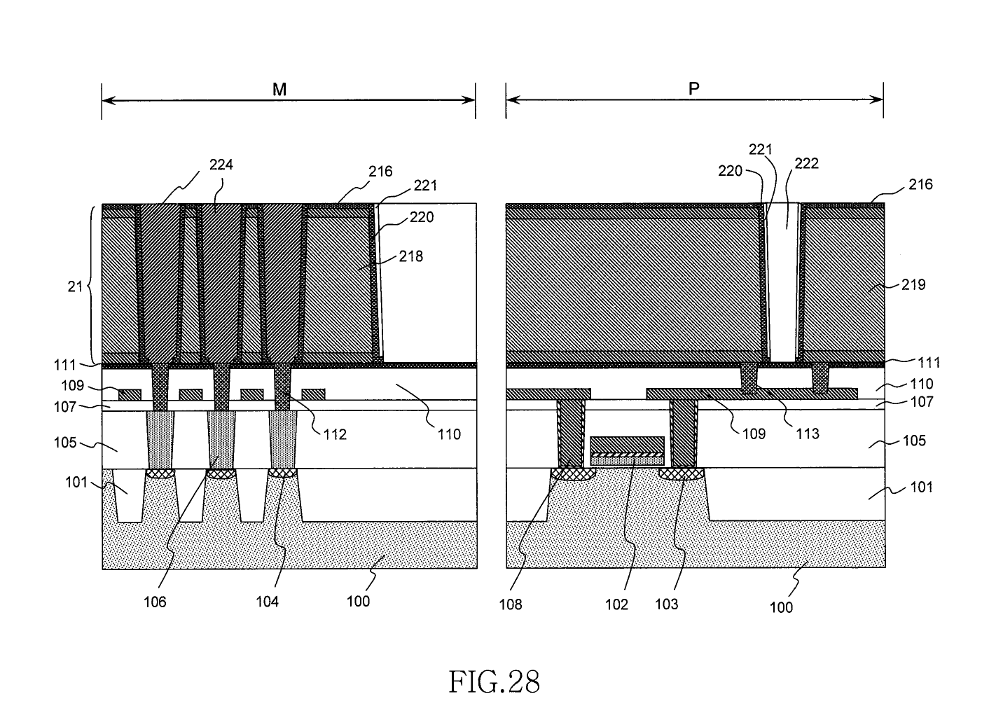

Next, the tungsten film 223 and the silicon oxide film 222 are polished by the CMP method, using the cap insulating layer 216 as a stopper. Through this process, storage electrodes 224 of the capacitor embedded in the openings 217a are formed as shown in FIG. 28.

In the above process, a first capacitor layer 21 including the storage electrodes 224, the tantalum oxide films (capacity insulating films) 220, and the plate electrode 218 is formed in the memory cell area M. At the same time, the wiring layer 219 is formed in the peripheral circuit area P. Thereafter, a second capacitor layer, a third capacitor layer, and so on is formed sequentially. Next, a manufacturing process of the second capacitor layer will be explained.

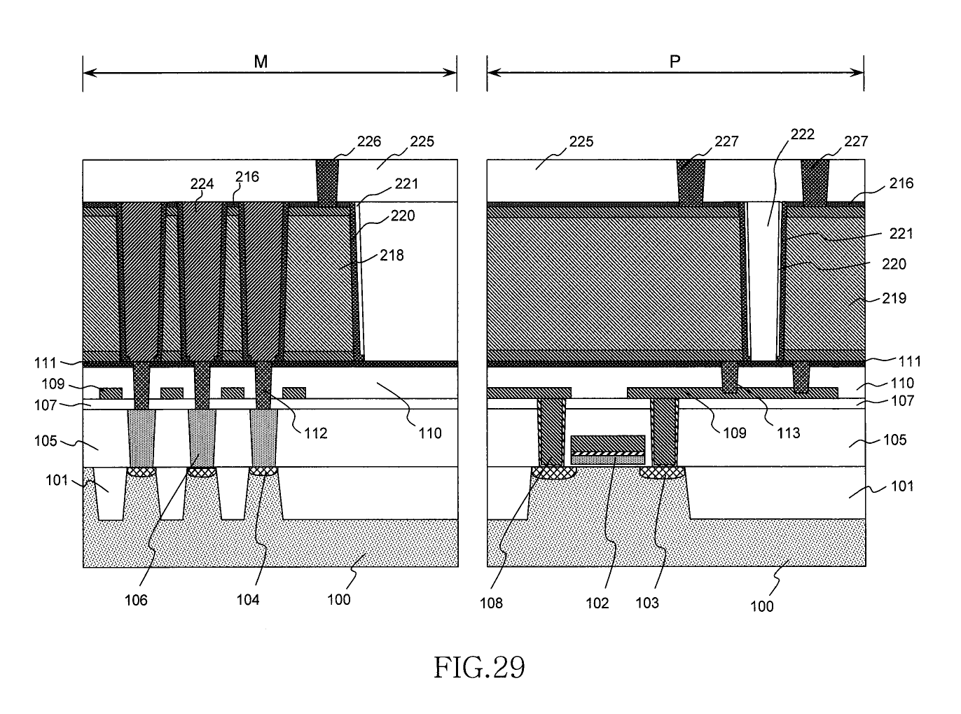

FIG. 29 to FIG. 35 show the manufacturing process of the second capacitor layer.

As shown in FIG. 29, a silicon oxide film 225 with a thickness of about 300 nm is formed on the whole surface. Next, a contact plug 226 is formed in the memory cell area M, and contact plugs 227 are formed in the peripheral circuit area P. The contact plug 226 is connected to the plate electrode 218, and the contact plugs 227 are connected to the wiring layer 219. For example, tungsten (W) can be used for the material of the contact plugs 226 and 227.

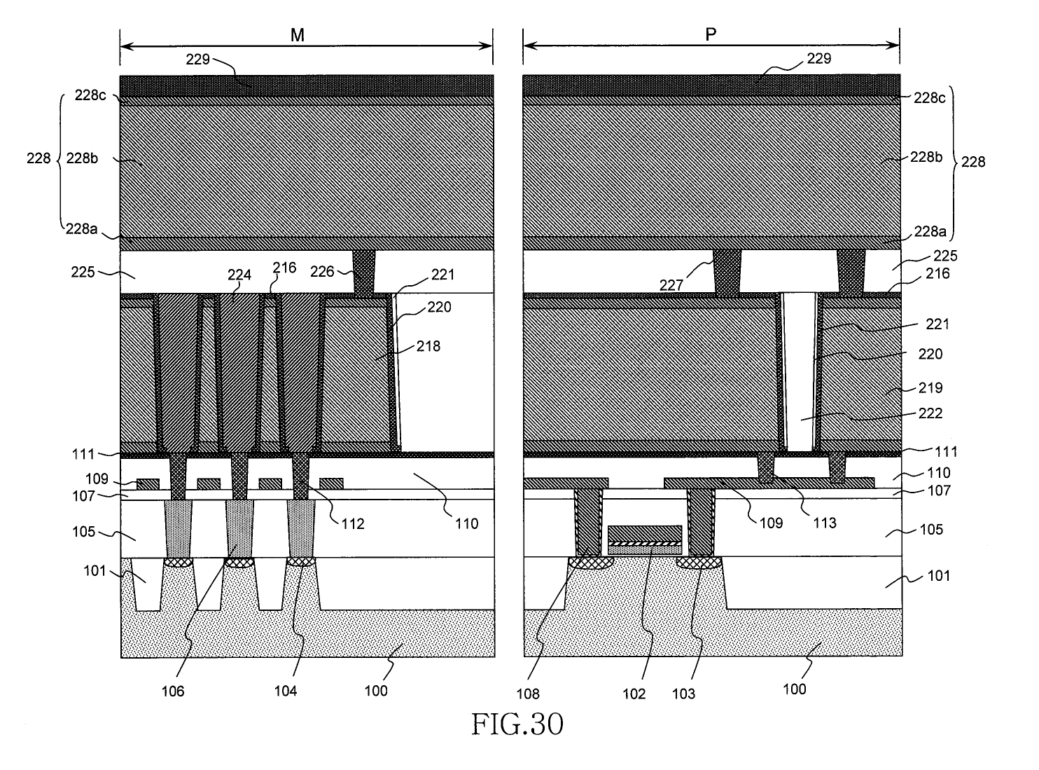

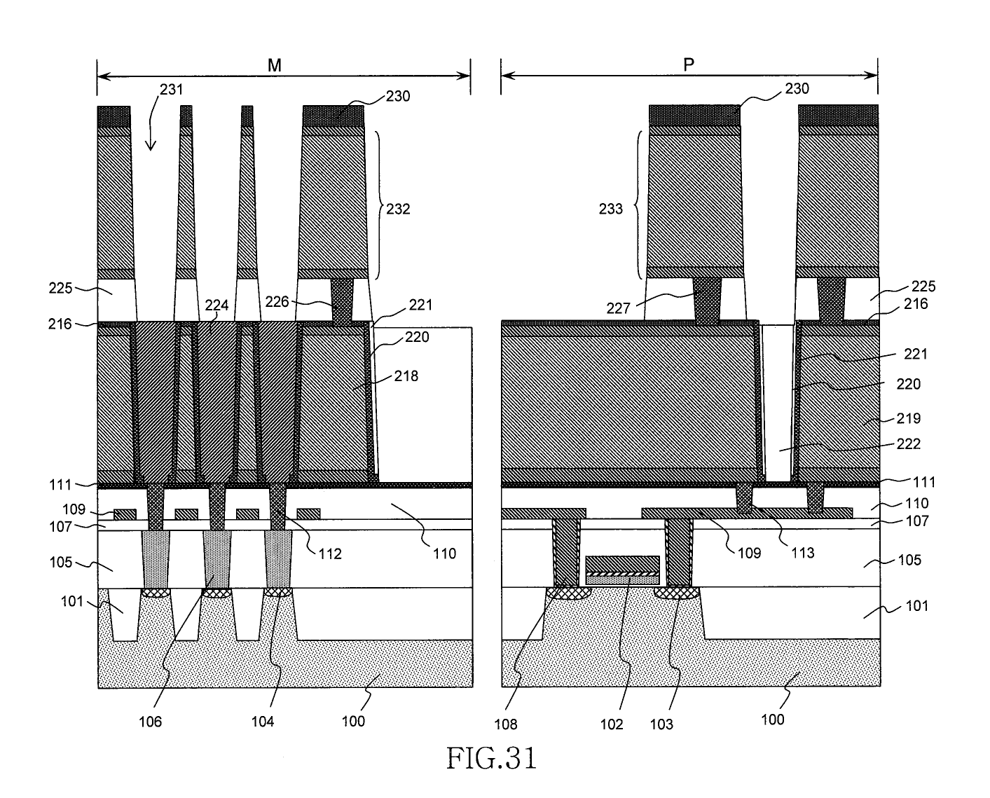

Next, a conductive film 228 is formed on the oxide film 225 and the contact plugs 226 and 227, and a silicon nitride film 229 with a thickness of about 200 nm is formed on the conductive film 228, as shown in FIG. 30. The conductive film 228 includes a Ti/TiN film 228a with a thickness of about 20 nm and about 30 nm respectively, an AlCu film 228 with a thickness of about 800 nm, and a TiN film 228c with a thickness of about 50 nm, laminated in this order. Next, as shown in FIG. 31, the silicon nitride film 229 is patterned, thereby forming a cap insulating layer 230. Further, the conductive film 228 (refer to FIG. 30) and the silicon oxide film 225 are patterned. As a result, a plate electrode 232 is formed in the memory cell area M, and a wiring layer 233 is formed in the peripheral circuit area P.

As shown in FIG. 31, planar positions of openings 231 as an areas in which the plate electrode 232 is not formed corresponds to planar positions of the storage electrodes 224, respectively. Therefore, corresponding upper surfaces of the storage electrodes 224 are exposed at the bottoms of the openings 231. The plate electrode 232 is electrically connected to the plate electrode 218 in the first layer via the contact plug 226. The wiring layer 233 is electrically connected to the wiring layer 219 in the first layer via the contact plug 227, depending on the function.

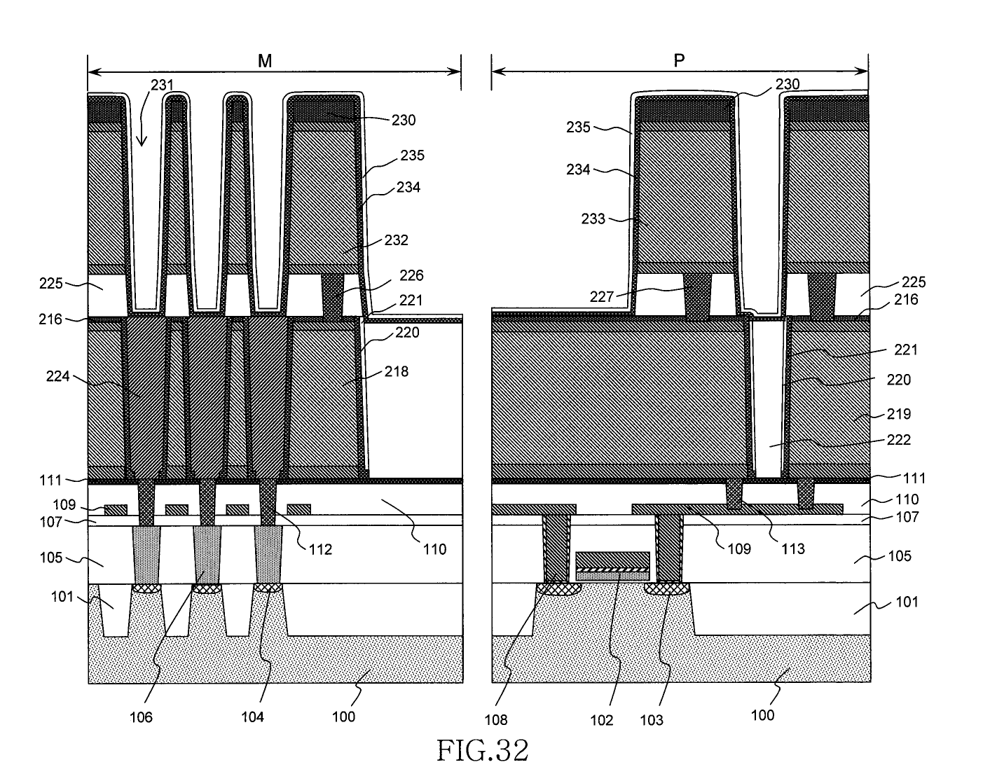

Next, as shown in FIG. 32, a tantalum oxide (Ta₂O₅) film 234 with a thickness of about 5 nm to be a capacity insulating film of the capacitor is formed on the whole surface, and a silicon oxide film 235 with a thickness of about 5 nm is formed to protect the tantalum oxide film 234, without removing the cap insulating layer 230, similarly to the process shown in FIG. 23.

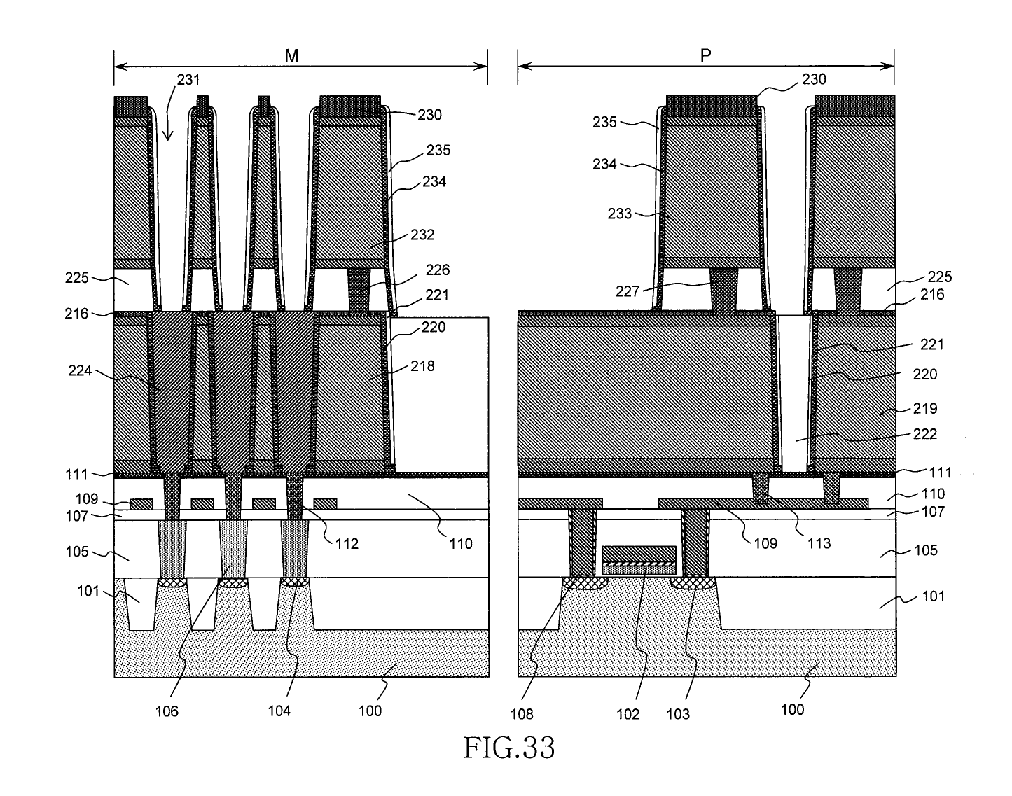

Next, as shown in FIG. 33, the whole surface is etched back, and the upper surfaces of the storage electrodes 224 are exposed at the bottoms of the openings 231, similarly to the process shown in FIG. 24. On the other hand, the tantalum oxide film 234 and the silicon oxide film 235 are kept remaining in the sidewalls of the plate electrode 232 and the sidewalls of the wiring layer 233, respectively.

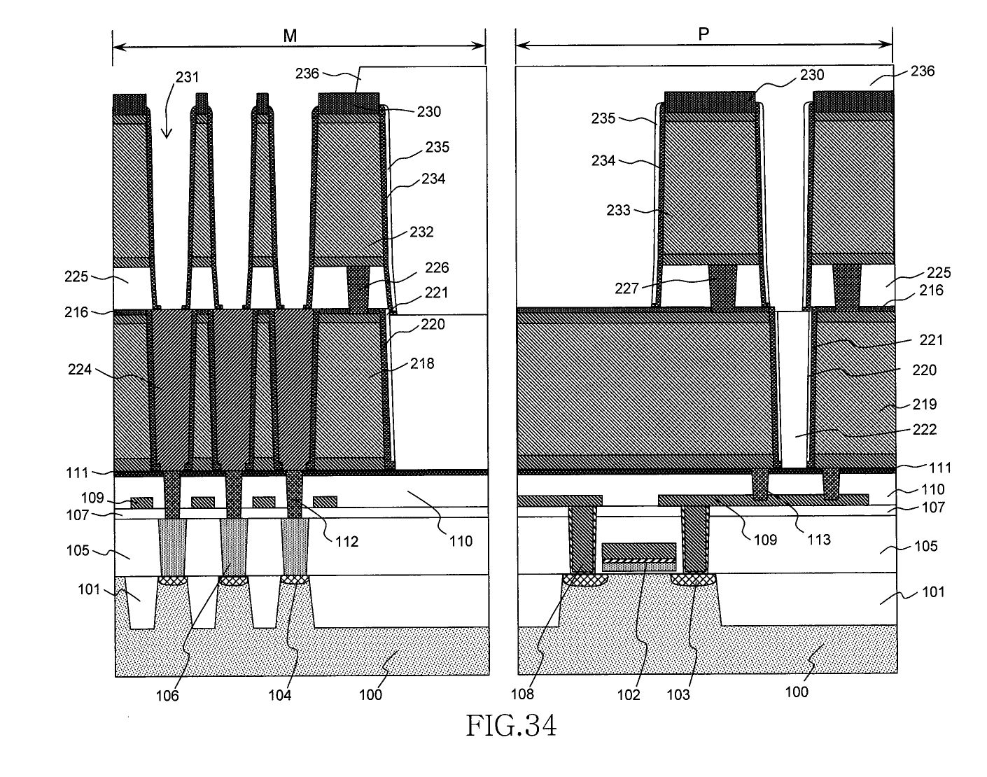

Next, as shown in FIG. 34, a silicon oxide film 236 with a large thickness is formed on the whole surface to fill the gap between the openings 231 and the wiring layer 233, similarly to the process shown in FIG. 25. Thereafter, the silicon oxide film 236 is flattened by the CMP method. Then, the peripheral circuit area P is covered with a mask layer (not shown), and a wet etching is carried out to selectively remove the silicon oxide film 236 in the memory cell area M and the silicon oxide film 235 within the openings 231, similarly to the process shown in FIG. 26.

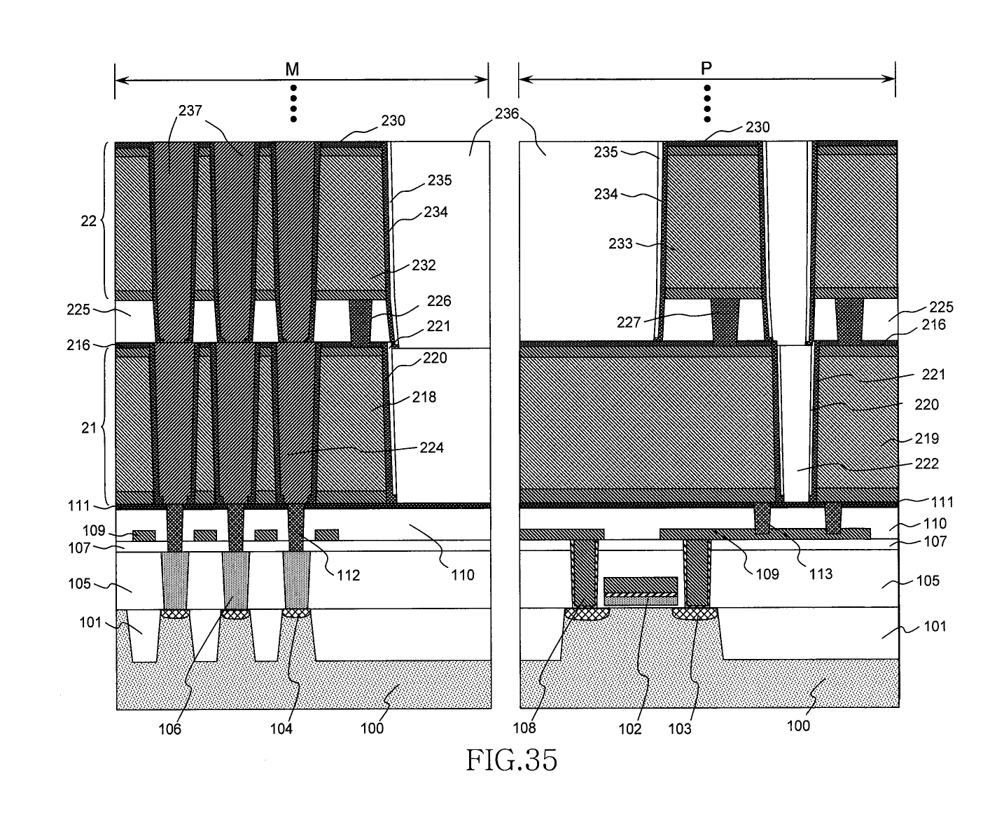

Next, a tantalum film is formed on the whole surface to fill the openings 231, and then the tungsten film and the silicon oxide film 236 are removed by the CMP method, using the cap insulating layer 230 as a stopper, similarly to the process shown in FIG. 27. As a result, storage electrodes 237 made of tungsten is embedded in the openings 231, as shown in FIG. 35.

In the above process, a second capacitor layer 22 including the storage electrodes 237, the tantalum oxide films (capacity insulating films) 234, and the plate electrode 232 is formed in the memory cell area M.

Thereafter, a process similar to that shown in FIG. 29 to FIG. 35 is repeatedly carried out, thereby laminating capacitor layers in a number (n layers) enough to obtain necessary electrostatic capacity.

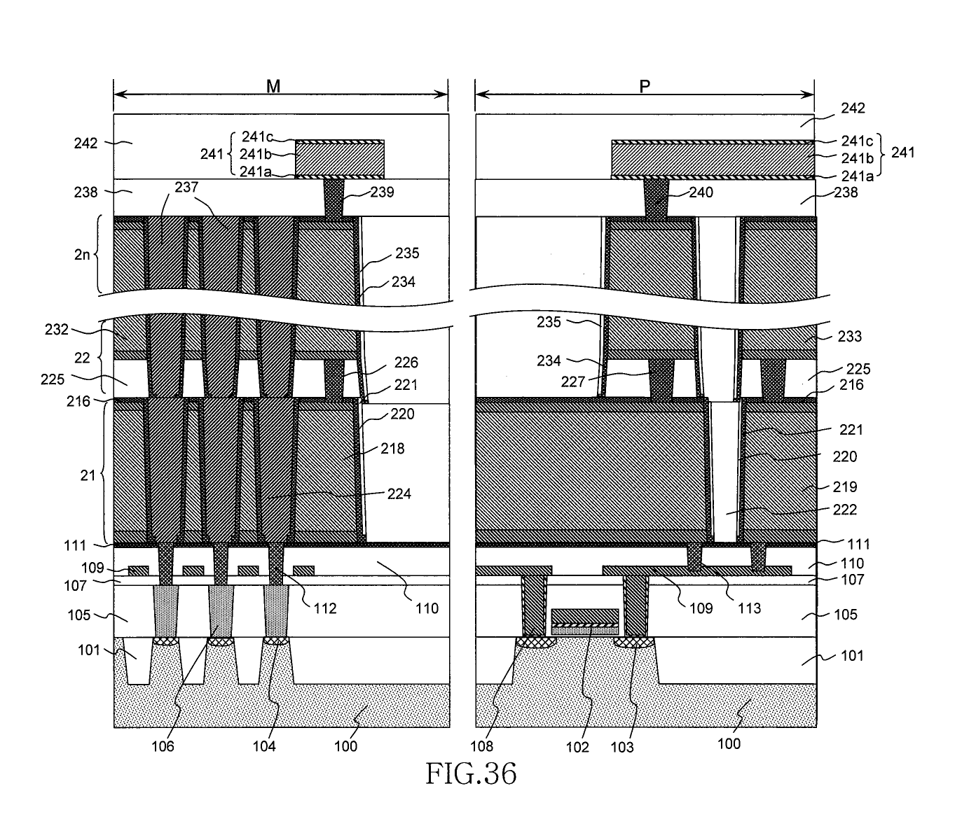

Next, as shown in FIG. 36, an inter-layer insulating film 238 is formed on the top capacitor layer 2n, and thereafter, a contact plug 239 which is connected to the plate electrode of the top layer capacitor is formed in the memory cell area M. A contact plug 240 which is connected to the top layer wiring layer is formed in the peripheral circuit area P. Next, a TiN/Ti film 241a, an AlCu film 241b, and a TiN film 241c are laminated on the inter-layer insulating film 238. The laminated films are patterned to form a wiring layer 241. Then, an insulating film 242 is formed to cover the wiring layer 241. Further, wiring connection plugs and upper layer wirings (not shown) are formed by a necessary number of layers, respectively. Lastly, a protection film is generated on the top wiring layer, and a connection hole from which an electrode pad is exposed is formed in the protection film.

Through the above process, plural capacitor layers are laminated in the memory cell area M, and plural wiring layers are laminated in the peripheral circuit area P, thereby completing a DRAM.

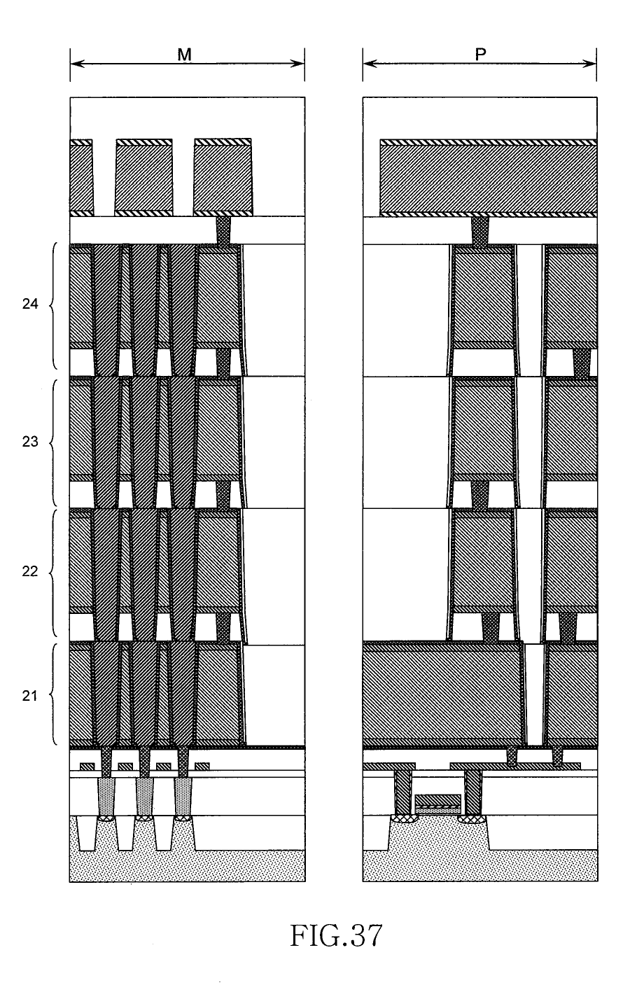

FIG. 37 is a cross-sectional diagram of the DRAM when there are four capacitor layers in the second embodiment.

The DRAM includes a first capacitor layer 21 with a thickness of about 900 nm, and a second capacitor layer 22, a third capacitor layer 23, and a fourth capacitor layer, each having a thickness of about 1,200 nm. Each of the capacitor layers 22, 23, and 24 includes an oxide film with a thickness of 300 nm below the plate electrode. Therefore, it is possible to realize a capacitor having a total thickness of 3,600 nm (900 nm+(1,200−300) nm×3=3,600 nm).

As explained above, in the present embodiment, plural capacitor layers having substantially the same structure are repeatedly formed, similarly to the first embodiment. Therefore, effects similar to those in the first embodiment can be obtained. In the present embodiment, AlCu is used as a main material of the plate electrode. Therefore, resistance of the wiring layer formed simultaneously with the plate electrode can be decreased sufficiently. Further, electric potential of the plate electrode can be stabilized.

In the first embodiment, only the contact plug is present as the element in the peripheral circuit area P that is positioned at the same height as that of each capacitor layer. On the other hand, according to the second embodiment, each wiring layer has an independent function in each layer in the peripheral circuit area P. Therefore, a high-functional peripheral circuit having complex wiring structure can be built into the DRAM. Consequently, the DRAM can enhance its performance, or an ultra-fine DRAM can be integrated in a hybrid LSI. When the functions are the same, the planar dimension of the peripheral circuit area can be reduced, thereby improving yield, and reducing cost.

While preferred embodiments of the present invention have been described hereinbefore, the present invention is not limited to the aforementioned embodiments and various modifications can be made without departing from the spirit of the present invention. It goes without saying that such modifications are included in the scope of the present invention.

While the plate electrode is formed first, and thereafter, the storage electrodes are formed in each of the above embodiments, the order of arrangement is not limit in the present invention. For example, the plate electrode can be formed after the storage electrodes are formed. However, in the present invention, when the plate electrode is formed first, various effects explained above can be obtained.

While a tungsten film is used for the plate electrode in the first embodiment, other conductive material can be also used instead of this material. For example, a laminated film of a Ti/TiN film, an AlCu film, and a TiN film can be also used as explained in the second embodiment. Materials of other insulating films and wiring layers can be also suitably changed.

For the material of the capacity insulating film, an aluminum oxide film or a hafnium oxide film, or a laminated film of these films can be also used, instead of the tantalum oxide film.

As described above, according to the present invention, since plural capacitor layers are laminated, the aspect ratio of each capacitor layer can be restricted. As a result, sufficient electrostatic capacity can be obtained while securing high yield. Particularly, when a new material is used following the miniaturization, the height of each capacitor layer can be determined to obtain an achievable aspect ratio in the manufacturing characteristics such as coverage of the material. When the electrostatic capacity for information storage is insufficient, this shortage can be compensated for by increasing the number of capacitor layers to be laminated. Therefore, when a new material is used, the DRAMs can be produced in high yield from the initial stage of development, thereby shortening the development period. When each capacitor layer is formed in substantially the similar process, the same device can be used repeatedly to form plural capacitor layers. As a result, increase in the manufacturing cost can be minimized.

When capacitor layers are laminated, the number of manufacturing steps increases. However, according to the present invention, the plate electrode and the contact plugs or the wiring layer in the peripheral circuit area are formed simultaneously using the same material in each capacitor layer. Therefore, increase in the number of manufacturing steps can be suppressed, and increase in the manufacturing cost can be minimized. Since the contact plugs or the wiring layer can be formed in the corresponding peripheral circuit area in each capacitor layer, the aspect ratio of the contact plug for connecting between the wiring layers in the peripheral circuit area can be restricted, as compared with the aspect ratio according to the conventional technique that requires an equivalent or deeper contact plug than the capacitor structure. Consequently, yield can be improved.

1-7. (canceled)

8. A method of manufacturing a semiconductor device comprising:
a first step of forming a first capacitor layer having a pillar-shaped first storage electrode, a first capacity insulating film that covers a side surface of the first storage electrode, and a first plate electrode that covers at least a part of the side surface of the first storage electrode via the first capacity insulating film, on a semiconductor substrate; and
a second step of forming a second capacitor layer having a pillar-shaped second storage electrode that is connected to the first storage electrode, a second capacity insulating film that covers a side surface of the second storage electrode, and a second plate electrode that covers at least a part of the side surface of the second storage electrode via the second capacity insulating film and that is connected to the first plate electrode, on the first capacitor layer.

9. The method of manufacturing a semiconductor device as claimed in claim 8, wherein
the first step includes:
a first sub-step of forming a film of a first electrode material on the semiconductor substrate;
a second sub-step of forming the first plate electrode having a first through-hole, by patterning the first electrode material;
a third sub-step of forming the first capacity insulating film on an inner wall of the first through-hole; and
a fourth sub-step of forming the first storage electrode, by filling a second electrode material into the first through-hole, and
the second step includes:
a fifth sub-step of forming a film of a third electrode material on the first capacitor layer;
a sixth sub-step of forming the second plate electrode having a second through-hole, by patterning the third electrode material;
a seventh sub-step of forming the second capacity insulating film on an inner wall of the second through-hole; and
an eighth sub-step of forming the second storage electrode, by filling a fourth electrode material into the second through-hole.

10. The method of manufacturing a semiconductor device as claimed in claim 9, wherein
a first insulating film is formed on the first electrode material after the first sub-step, a first cap insulating layer is formed on the first plate electrode by forming the first insulating film in the same pattern as that of the first plate electrode at the second sub-step, and the third sub-step is carried out without removing the first cap insulating layer, and
a second insulating film is formed on the third electrode material after the fifth sub-step, a second cap insulating layer is formed on the second plate electrode by forming the second insulating film in the same pattern as that of the second plate electrode at the sixth sub-step, and the seventh sub-step is carried out without removing the second cap insulating layer.

11. The method of manufacturing a semiconductor device as claimed in claim 10, wherein
the fourth sub-step includes a step of polishing the second electrode material, using the first cap insulating layer as a stopper, and
the eighth sub-step includes a step of polishing the fourth electrode material, using the second cap insulating layer as a stopper.

12. The method of manufacturing a semiconductor device as claimed in claim 9, wherein
the third sub-step includes a step of forming a first protection insulating film that covers the first capacity insulating film, a step of etching back the first protection insulating film, a step of etching back the first capacity insulating film, and a step of removing the first protection insulating film, and
the seventh sub-step includes a step of forming a second protection insulating film that covers the second capacity insulating film, a step of etching back the second protection insulating film, a step of etching back the second capacity insulating film, and a step of removing the second protection insulating film.

13. The method of manufacturing a semiconductor device as claimed in claim 8, wherein the first and the second capacity insulating films are any one of a tantalum oxide film, an aluminum oxide film, a hafnium oxide film, and a laminated film of an aluminum oxide film and a hafnium oxide film.

14. The method of manufacturing a semiconductor device as claimed in claim 9, wherein a contact plug is formed in a peripheral circuit area, by patterning at the second and the fourth sub-steps.

15. The method of manufacturing a semiconductor device as claimed in claim 10, wherein a contact plug is formed in a peripheral circuit area, by patterning at the second and the fourth sub-steps.

16. The method of manufacturing a semiconductor device as claimed in claim 11, wherein a contact plug is formed in a peripheral circuit area, by patterning at the second and the fourth sub-steps.

17. The method of manufacturing a semiconductor device as claimed in claim 12, wherein a contact plug is formed in a peripheral circuit area, by patterning at the second and the fourth sub-steps.

18. The method of manufacturing a semiconductor device as claimed in claim 13, wherein a contact plug is formed in a peripheral circuit area, by patterning at the second and the fourth sub-steps.

19. The method of manufacturing a semiconductor device as claimed in claim 10, wherein a wiring layer is formed in a peripheral circuit area, by patterning at the second and the fourth sub-steps.

20. The method of manufacturing a semiconductor device as claimed in claim 10, wherein a wiring layer is formed in a peripheral circuit area, by patterning at the second and the fourth sub-steps.

21. The method of manufacturing a semiconductor device as claimed in claim 11, wherein a wiring layer is formed in a peripheral circuit area, by patterning at the second and the fourth sub-steps.

22. The method of manufacturing a semiconductor device as claimed in claim 12, wherein a wiring layer is formed in a peripheral circuit area, by patterning at the second and the fourth sub-steps.

23. The method of manufacturing a semiconductor device as claimed in claim 13, wherein a wiring layer is formed in a peripheral circuit area, by patterning at the second and the fourth sub-steps.

24. A method of manufacturing a semiconductor device having a first capacitor layer which includes a plurality of first storage electrodes and a first plate electrode provided between the plurality of first storage electrodes through a first capacity insulating film, and a second capacitor layer which is stacked on the first capacitor layer and includes a plurality of second storage electrodes each electrically connected to an associated one of the first storage electrodes, respectively, and a second plate electrode provided between the plurality of second storage electrodes through a second capacity insulating film and electrically connected to the first plate electrode, the method comprising:
forming a first layer;
forming a plurality of first through holes in the first layer;
forming the plurality of first storage electrodes in the plurality of first through holes, respectively;
forming an insulating film on the first layer to contact each of the plurality of first storage electrodes,
forming a second layer on the insulating film;
forming a plurality of second through holes in the second layer; and
forming the plurality of second storage electrodes in the plurality of second through holes, respectively.

25. The method as claimed in claim 24, wherein the insulating film consists of silicon nitride film.

26. The method as claimed in claim 25, wherein the plurality of first storage electrodes and the plurality of second storage electrodes are electrically connected through an opening which is formed in the silicon nitride film.

27. The method as claimed in claim 24, wherein an opening for electrically connecting the plurality of first storage electrodes and the plurality of second storage electrodes is formed in the insulating film after the plurality of second through holes are formed and before the plurality of second storage electrodes are formed in the plurality of second through holes.

28. The method as claimed in claim 26, wherein the opening is formed after the plurality of second through holes are formed and before the plurality of second storage electrodes are formed in the plurality of second through holes.

29. The method as claimed in claim 24, wherein the first layer and the second layer are conductive layers, and used as the first plate electrode and the second plate electrode, respectively.
